(19) United States
(12) Patent Application Publication
(10) Pub. No.: US 2024/0423031 A1
(43) Pub. Date: Dec. 19, 2024

(54) DISPLAY DEVICE AND MANUFACTURING METHOD THEREOF

(71) Applicant: Samsung Display Co., Ltd., Yongin-si (KR)

(72) Inventor: JONGHYUN CHOI, Yongin-si (KR)

(21) Appl. No.: 18/634,761

(22) Filed: Apr. 12, 2024

(30) Foreign Application Priority Data
Jun. 16, 2023 (KR) 10-2023-0077180

(51) Int. Cl. H10K 59/124; H10K 59/12; H10K 59/122

(52) U.S. Cl. CPC H10K 59/124; H10K 59/1201; H10K 59/122

(57) ABSTRACT

Provided is a display device includes a base layer, a first transistor above the base layer, and including a first gate and a first semiconductor pattern including a first source, a first active region corresponding to the first gate, and a first drain, a second transistor above the base layer and including an upper gate and a second semiconductor pattern including a second source, a second active region below the upper gate, and a second drain, insulating layers covering the first and second transistors, a gate-insulating layer covering the second active region, and in which openings corresponding to the second source and the second drain are defined, a first protective pattern in the first opening, above the second source, and including a same material as the upper gate, and a second protective pattern in the second opening, above the second drain, and including a same material as the upper gate.

### CROSS-REFERENCE TO RELATED APPLICATIONS

The present application claims priority to, and the benefit of, Korean Patent Application No. 10-2023-0077180, filed on Jun. 16, 2023, in the Korean Intellectual Property Office, the entire disclosure of which is incorporated herein by reference.

### BACKGROUND

The present disclosure herein relates to a display device including a protective pattern for protecting a semiconductor pattern.

Display devices include a plurality of pixels and a driving circuit (e.g., a scan-driving circuit and a data-driving circuit) configured to control the plurality of pixels. Each of the plurality of pixels includes a display element and a pixel-driving circuit configured to control the display element. The pixel-driving circuit may include a plurality of organically connected thin film transistors.

The scan-driving circuit and/or the data-driving circuit may be formed through the same process as the plurality of pixels. These driving circuits may include a plurality of thin film transistors organically connected to each other.

According to a driving timing, different bias voltages are respectively applied to control electrodes, input electrodes, and output electrodes of the thin film transistors of the pixel-driving circuit. According to a driving timing, different bias voltages are also respectively applied to control electrodes, input electrodes, and output electrodes of the thin film transistors of the scan-driving circuit and/or the data-driving circuit.

### SUMMARY

The present disclosure provides a display device including a protective pattern for protecting a semiconductor pattern of a transistor.

The present disclosure also provides a method of manufacturing a display device, the method having a simple manufacturing process for forming a contact hole.

One or more embodiments of the present disclosure provide a display device including a base layer, a first transistor above the base layer, and including a first gate and a first semiconductor pattern including a first source, a first active region corresponding to the first gate, and a first drain, a second transistor above the base layer and including an upper gate and a second semiconductor pattern including a second source, a second active region below the upper gate, and a second drain, insulating layers covering the first transistor and the second transistor, a gate-insulating layer covering the second active region, and in which a first opening corresponding to the second source, and a second opening corresponding to the second drain, are defined, a first protective pattern in the first opening, above the second source, and including a same material as the upper gate, and a second protective pattern in the second opening, above the second drain, and including a same material as the upper gate.

The second transistor may further include a lower gate below the second active region, wherein the lower gate and the upper gate are electrically connected to each other through a first contact hole passing through the gate-insulating layer and through a portion of the insulating layers between the lower gate and the upper gate, and wherein at least any one of the lower gate or the upper gate is configured to receive a separate signal.

The lower gate may be at a same layer as the first gate, and may include a same material as the first gate.

A portion of the first protective pattern may overlap the gate-insulating layer, wherein a remaining portion of the first protective pattern does not overlap the gate-insulating layer, wherein a portion of the second protective pattern overlaps the gate-insulating layer, and wherein a remaining portion of the second protective pattern does not overlap the gate-insulating layer.

An insulating protrusion portion may be defined by an inner side surface of the gate-insulating layer, wherein at least a portion of the insulating protrusion portion overlaps the portion of the first protective pattern and the portion of the second protective pattern.

The insulating protrusion portion may be provided in plurality, wherein the insulating protrusion portions are spaced apart from each other at regular intervals along the inner side surface.

The inner side surface may include a first surface, and a second surface that is longer than the first surface, wherein the insulating protrusion portion is provided in plurality, wherein the insulating protrusion portions are arranged along the second surface, and wherein the second surface is closer to the second active region than the first surface.

The first protective pattern and the second protective pattern may include a protective pattern body, and a protective pattern protrusion portion protruding from the protective pattern body, wherein at least a portion of the protective pattern protrusion portion overlaps the gate-insulating layer.

The protective pattern protrusion portion may be provided in plurality, wherein the protective pattern protrusion portions are spaced apart from each other along an outer side surface of each of the first protective pattern and the second protective pattern.

An inner side surface of the gate-insulating layer defining the opening may include a first surface, and a second surface that is longer than the first surface, wherein the protective pattern protrusion portion is provided in plurality, wherein the protective pattern protrusion portions are arranged along the second surface, and wherein the second surface among the inner side surfaces is closest to the second active region.

A portion of the gate-insulating layer may contact a lower surface of the upper gate and may contact an upper surface of the second active region.

The display device may further include a first connection electrode contacting at least one of the first source or the first drain through a second contact hole passing through the insulating layers and the gate-insulating layer, and a second connection electrode contacting at least one of the first protective pattern or the second protective pattern through a third contact hole passing through the insulating layers and the gate-insulating layer.

The first semiconductor pattern may include a polysilicon semiconductor, wherein the second semiconductor pattern includes an oxide semiconductor.

The base layer may include a pixel region overlapping the first transistor and the second transistor, and a boundary region adjacent to the pixel region, wherein a boundary opening corresponding to the boundary region is defined by the insulating layers and the gate-insulating layer.

The base layer may include a non-bending region, and a bending region that is bendable and that is adjacent to the non-bending region, wherein a bending groove overlapping the bending region is defined by the insulating layers and the gate-insulating layer.

In one or more embodiments of the present disclosure, a method for manufacturing a display device may include preparing a preliminary display device including a base layer including a display region including a pixel region, and a boundary region adjacent to the pixel region, and a non-display region including a bending region that is bendable, a first transistor including a first gate, and a first semiconductor pattern including a first source, a first active region, and a first drain, a preliminary second transistor including a lower gate and a preliminary second semiconductor pattern, and a lower insulating layer covering the first transistor and the preliminary second transistor, forming a first contact hole overlapping the lower gate in the lower insulating layer, forming a first opening overlapping a second source region of the preliminary second transistor in the lower insulating layer, forming a second opening overlapping a second drain region of the preliminary second transistor in the lower insulating layer, forming an upper gate contacting the lower gate through the first contact hole, forming a first protective pattern in the first opening, forming a second protective pattern in the second opening, forming a second transistor by forming a second semiconductor pattern including a second source, a second active region, and a second drain from the preliminary second semiconductor pattern, forming an upper insulating layer covering the second transistor, and substantially simultaneously forming a second contact hole defined by the upper insulating layer and the lower insulating layer, and corresponding to each of the first source and the first drain, and a third contact hole defined by the upper insulating layer and the lower insulating layer, and corresponding to each of the second source and the second drain.

In the forming of the first contact hole, the forming the first opening, and the forming the second opening, a boundary opening corresponding to the boundary region may be substantially simultaneously formed in the lower insulating layer.

In the forming of the first contact hole, forming the first opening, and forming the second opening, a bending groove overlapping the bending region may be substantially simultaneously formed in the lower insulating layer.

The forming of the first contact hole, the forming of the first opening, and the forming of the second opening may include forming a photoresist layer on the lower insulating layer, and exposing the photoresist layer to light using a mask including a light-transmissive region, a non-light-transmissive region, and a semi-light-transmissive region on the photoresist layer, wherein the semi-light-transmissive region corresponds to the first opening and the second opening, and wherein the light-transmissive region corresponds to the first contact hole.

The forming of the first contact hole, the forming of the first opening, and the forming of the second opening may include forming a photoresist layer on the lower insulating layer, and exposing the photoresist layer to light using a mask including a light-transmissive region and a non-light-transmissive region on the photoresist layer, wherein the light-transmissive region corresponds to the first contact hole, the first opening, and the second opening.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a perspective view of an electronic device according to one or more embodiments of the present disclosure;

FIG. 2 is a plan view of a display panel according to one or more embodiments of the present disclosure;

FIG. 3 is a perspective view of the display panel and an electronic module according to one or more embodiments of the present disclosure;

FIG. 4 is a cross-sectional view of a display device according to one or more embodiments of the present disclosure;

FIG. 5 is an equivalent circuit diagram of a pixel according to one or more embodiments of the present disclosure;

FIG. 6 is an enlarged plan view of a portion of a display region according to one or more embodiments of the present disclosure;

FIG. 7 is a cross-sectional view taken along the line II-II′ of FIG. 6 according to one or more embodiments of the present disclosure;

FIG. 8 is a cross-sectional view of a base layer and a circuit layer according to one or more embodiments of the present disclosure;

FIG. 9 is a plan view of a portion AA of FIG. 8 according to one or more embodiments of the present disclosure;

FIG. 10 is a cross-sectional view taken along the line III-III′ of FIG. 9 according to one or more embodiments of the present disclosure;

FIG. 11 is a cross-sectional view taken along the line IV-IV′ of FIG. 9 according to one or more embodiments of the present disclosure;

FIG. 12 is a plan view of the portion AA of FIG. 8 according to one or more embodiments of the present disclosure;

FIG. 13 is a cross-sectional view taken along the line V-V′ of FIG. 12 according to one or more embodiments of the present disclosure;

FIG. 14 is a cross-sectional view taken along the line VI-VI′ of FIG. 12 according to one or more embodiments of the present disclosure;

FIGS. 15 to 18 are plan views of the portion AA of FIG. 8 according to one or more embodiments of the present disclosure;

FIG. 19 is a cross-sectional view taken along the line I-I′ of FIG. 2 according to one or more embodiments of the present disclosure;

FIGS. 20A to 20J are cross-sectional views illustrating some operations of a method of manufacturing a display device according to one or more embodiments of the present disclosure; and

FIGS. 21A to 21C are cross-sectional views illustrating some operations of the method of manufacturing the display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

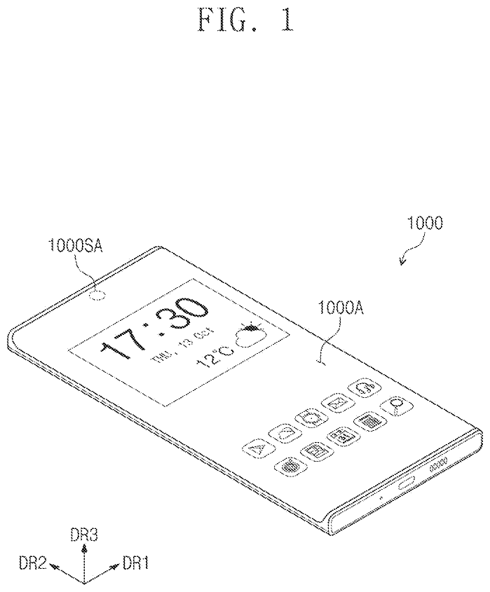

FIG. 1 is a perspective view of an electronic device according to one or more embodiments of the present disclosure.

Referring to FIG. 1, in one or more embodiments, a mobile phone is illustrated as an electronic device 1000. Without being limited thereto, however, the electronic device 1000 may be a tablet, a monitor, a television, a car navigation system, a game machine, or a wearable device.

The electronic device 1000 may display an image through a display region 1000A. The display region 1000A may include a plane defined by a first direction DR1 and a second direction DR2. The display region 1000A may further include curved surfaces respectively bent from at least two sides of the plane. However, the shape of the display region 1000A is not limited thereto. For example, the display region 1000A may include only the plane, or may further include at least two or more (e.g., four) curved surfaces respectively bent from respective ones of the four sides of the plane.

A partial region of the display region 1000A may be defined as a sensing region 1000SA. Although one sensing region 1000SA is illustrated in FIG. 1 as an example, the number of the sensing region 1000SA is not limited thereto. The sensing region 1000SA may be a portion of the display region 1000A, and may have higher optical signal transmittance than other regions of the display region 1000A. Accordingly, an image may be displayed through the sensing region 1000SA, and an optical signal may be provided through the sensing region 1000SA.

The thickness direction of the electronic device 1000 may be a third direction DR3, which is a normal direction of the display region 1000A. The front (or upper surface) and rear surface (or lower surface) of members constituting the electronic device 1000 may be defined based on the third direction DR3.

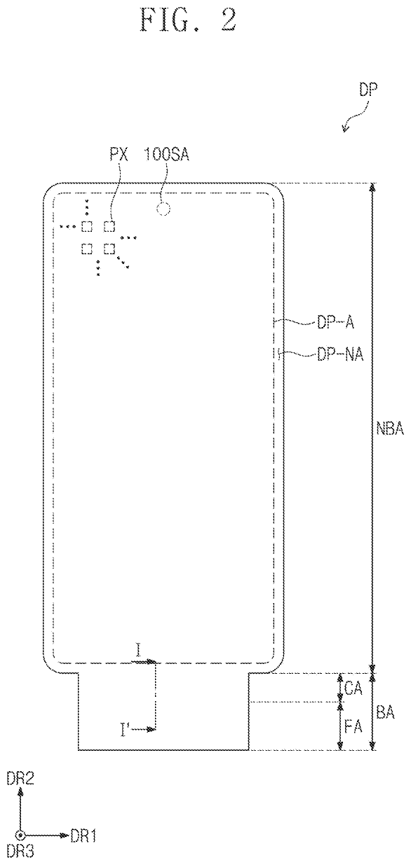

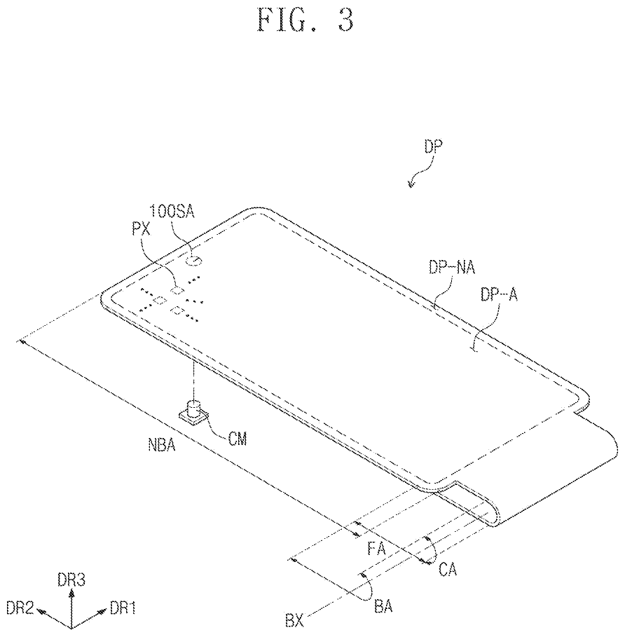

FIG. 2 is a plan view of a display panel according to one or more embodiments of the present disclosure, and FIG. 3 is a perspective view of the display panel and an electronic module according to one or more embodiments of the present disclosure.

Referring to FIGS. 2 and 3, the electronic device 1000 (see FIG. 1) may include an electronic module CM located in a region overlapping a sensing region 100SA. The sensing region 100SA may correspond to the sensing region 1000SA illustrated in FIG. 1. The electronic module CM may receive an optical signal provided from the outside through the sensing region 100SA, or may output an optical signal through the sensing region 100SA. For example, the electronic module CM (see FIG. 3) may be a camera module, a sensor configured to measure the distance between an object and a mobile phone, such as a proximity sensor, a sensor configured to recognize a part of a user's body (e.g., fingerprint, iris, or face), or a small lamp/light configured to output light, but the present disclosure is not particularly limited thereto.

The display panel DP may include a display region DP-A and a non-display region DP-NA. The display region DP-A may correspond to the display region 1000A illustrated in FIG. 1. The non-display region DP-NA may be adjacent to the display region DP-A, and may surround at least a portion of the display region DP-A. A plurality of pixels PX may be located in the display region DP-A. A light-emitting element may be located in the display region DP-A, and may be omitted from the non-display region DP-NA. The pixels PX may be located in each of the sensing region 100SA and the display region DP-A. The configurations of the pixels PX located in the sensing region 100SA and the display region DP-A may be different from each other.

The display panel DP is bendable and therefore may include a non-bending region NBA and a bending region BA. The bending region BA may extend from the non-bending region NBA, and may be bent. The bending region BA may include a curvature region CA having a curvature (e.g., predetermined curvature) in a bent state and a facing region FA facing the non-bending region NBA in a bent state.

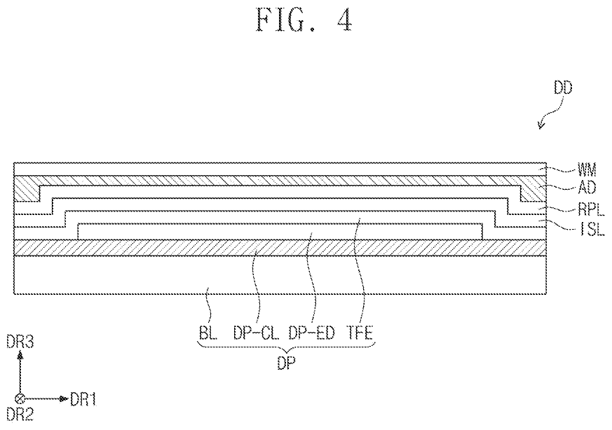

FIG. 4 is a cross-sectional view of a display device according to one or more embodiments of the present disclosure.

Referring to FIG. 4, the display device DD may include a display panel DP, a sensor layer ISL, a reflection prevention layer RPL, and a window WM. The reflection prevention layer RPL and the window WM may be coupled to each other by an adhesive layer AD. The display device DD illustrated in FIG. 4 may be a part or all of the electronic device 1000 illustrated in FIG. 1 (see FIG. 1) and is not particularly limited.

The display panel DP may be configured to substantially generate an image. The display panel DP may be a light-emitting display panel, and for example, the display panel DP may be an organic light-emitting display panel, an inorganic light-emitting display panel, a micro LED display panel, or a nano LED display panel. The display panel DP may also be referred to as a display layer.

The display panel DP may include a base layer BL, a circuit layer DP-CL, a light-emitting element layer DP-ED, and an encapsulation layer TFE.

The base layer BL may overlap the display region DP-A and the non-display region DP-NA of FIG. 3. The display region DP-A, the non-display region DP-NA, the non-bending region NBA, and the bending region BA defined in FIG. 3 may be equally applied to the base layer BL. The base layer BL may be a member configured to provide a base surface on which the circuit layer DP-CL is located. The base layer BL may be a rigid substrate or a flexible substrate capable of being bent, folded, or rolled. The base layer BL may be a glass substrate, a metal substrate, a polymer substrate, or the like. However, the present disclosure is not limited thereto, and the base layer BL may be an inorganic layer, an organic layer, or a composite material layer.

The base layer BL may have a multi-layered structure. For example, the base layer BL may include a first synthetic resin layer, a multi-layered or single-layered inorganic layer, and a second synthetic resin layer located on the multi-layered or single-layered inorganic layer. Each of the first and second synthetic resin layers may include a polyimide-based resin, but the present disclosure is not particularly limited thereto.

The circuit layer DP-CL may be located on the base layer BL. The circuit layer DP-CL may include an insulating layer, a semiconductor pattern, a conductive pattern, and a signal line.

The light-emitting element layer DP-ED may be located on the circuit layer DP-CL. The light-emitting element layer DP-ED may include a light-emitting element. For example, the light-emitting element may include an organic light-emitting material, an inorganic light-emitting material, an organic-inorganic light-emitting material, a quantum dot, a quantum rod, a micro LED, or a nano LED.

The encapsulation layer TFE may be located on the light-emitting element layer DP-ED. The encapsulation layer TFE may protect the light-emitting element layer DP-ED from moisture, oxygen, and foreign substances, such as dust particles. The encapsulation layer TFE may include at least one inorganic layer. The encapsulation layer TFE may include a stacked structure of an inorganic layer/an organic layer/an inorganic layer.

The sensor layer ISL may be located on the display panel DP. The sensor layer ISL may sense an external input applied from the outside. The external input may be a user's input. The user's input may include various types of external inputs, such as a part of the user's body, light, heat, pressure, or a pen.

The sensor layer ISL may be formed on the display panel DP through a continuous process. In this case, the sensor layer ISL may be directly located on the display panel DP. Here, the expression “being directly located” may mean that a third component is not located between the sensor layer ISL and the display panel DP. That is, a separate adhesive member may not be located between the sensor layer ISL and the display panel DP.

The reflection prevention layer RPL may be directly located on the sensor layer ISL. The reflection prevention layer RPL may reduce the reflectance of external light incident from the outside of the display device DD. The reflection prevention layer RPL may be formed on the sensor layer ISL through a continuous process. The reflection prevention layer RPL may include color filters. The color filters may have an arrangement (e.g., predetermined arrangement). For example, the color filters may be arranged in consideration of the light-emitting colors of pixels included in the display panel DP. In addition, the reflection prevention layer RPL may further include a black matrix adjacent to the color filters. A detailed description of the reflection prevention layer RPL will be given later.

In one or more embodiments of the present disclosure, the sensor layer ISL may be omitted. In this case, the reflection prevention layer RPL may be directly located on the display panel DP. In one or more embodiments of the present disclosure, the positions of the sensor layer ISL and the reflection prevention layer RPL may be interchanged with each other.

In one or more embodiments of the present disclosure, the display device DD may further include an optical layer located on the reflection prevention layer RPL. For example, the optical layer may be formed on the reflection prevention layer RPL through a continuous process. The optical layer may improve the front luminance of the display device DD by controlling the direction of light incident from the display panel DP. For example, the optical layer may include an organic insulating layer, in which openings are defined so as to respectively correspond to the light-emitting regions of pixels included in the display panel DP, and a high refractive layer configured to cover the organic insulating layer and fill the openings. The high refractive layer may have a higher refractive index than the organic insulating layer.

The window WM may provide a front surface of the electronic device 1000 (see FIG. 1). The window WM may include a glass film or a synthetic resin film as a base film. The window WM may further include a reflection prevention layer or an anti-fingerprint layer. The window WM may include a glass film or a synthetic resin film.

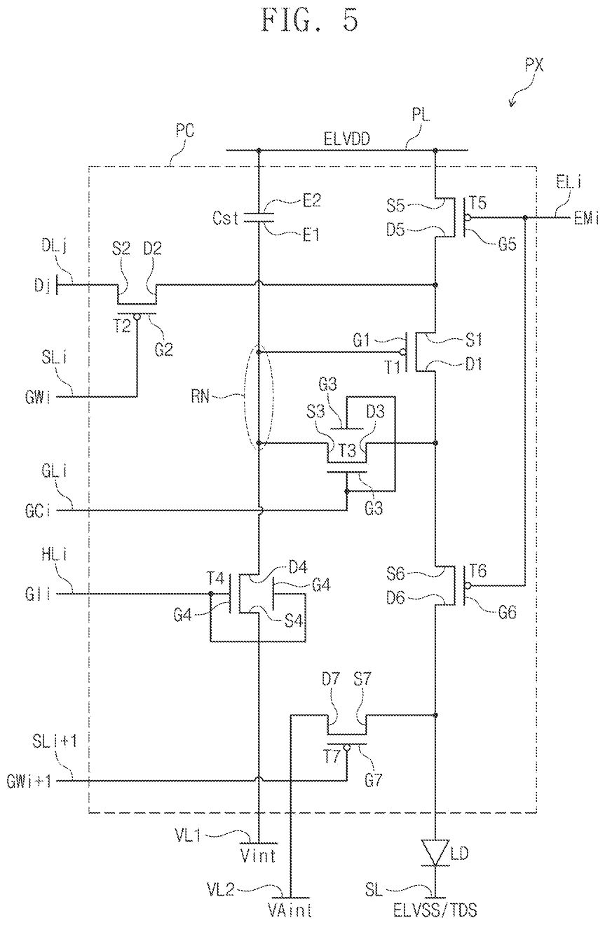

FIG. 5 is an equivalent circuit diagram of a pixel according to one or more embodiments of the present disclosure.

FIG. 5 illustrates a pixel PX connected to an i-th scan line SLi of a first group and connected to a j-th data line DLj. The pixel PX may include a pixel-driving circuit PC (hereinafter referred to as a pixel circuit) and a light-emitting element LD.

The first and second driving voltage lines VL1 and VL2 may transmit a first initialization voltage Vint and a second initialization voltage Vaint to the pixel PX, respectively.

The i-th scan line HLj, the i-th scan line GLj, the i-th scan line SLi, (i+1)-th scan line SLi+1, and the i-th light-emitting line ELi may transmit a i-th initialization scan signal Glj, a i-th compensation scan signal GCj, a i-th write scan signal GWi, a i-th black scan signal GWi+1, and a i-th light emitting control signal EMi to the pixel PX, respectively. The j-th data line DLj transmits an j-th data signal Dj to the pixel PX. The j-th data signal Dj may have a voltage level corresponding to an image signal input to the electronic device 1000 (see FIG. 1).

In one or more embodiments, the pixel-driving circuit PC may include first to seventh transistors T1 to T7 and a capacitor Cst. In one or more embodiments, the first transistor T1, the second transistor T2, and the fifth to seventh transistors T5, T6, and T7 are described as a P-type transistor, and the third transistor T3 and the fourth transistor T4 are described as an N-type transistor. The N-type transistor may be an oxide thin film transistor, and the P-type transistor may be a silicon transistor. Without being limited thereto, however, the first to seventh transistors T1 to T7 may be implemented as any one of a P-type transistor or an N-type transistor.

An N-type transistor, which is an oxide thin film transistor, may include a dual gate. The gate G3 of the third transistor T3 of FIG. 5 may be provided in the number of two, and the gates G3 may be electrically connected to an i-th scan line GLi of a second group. The gate G4 of the fourth transistor T4 of FIG. 5 may be provided in the number of two, and the gates G4 may be electrically connected to an i-th scan line HLi of a third group. As the electron mobility of the oxide thin film transistor is low compared to that of the silicon transistor, the dual gate may compensate for a small current flowing therethrough.

The input region (or input electrode) of the N-type transistor is described as a drain (or drain region), the input region of the P-type transistor is described as a source (or source region), the output region (or output electrode) of the N-type transistor is described as a source (or source region), and the output region of the P-type transistor is described as a drain (or drain region). In addition, in one or more embodiments of the present disclosure, at least one of the first to seventh transistors T1, T2, T3, T4, T5, T6, or T7 may be omitted.

In one or more embodiments, the first transistor T1 may be a driving transistor, and the second transistor T2 may be a switching transistor. The capacitor Cst is electrically connected between a power line PL, which receives a first power voltage ELVDD, and a reference node RN. The capacitor Cst includes a first electrode E1 electrically connected to the reference node RN, and a second electrode E2 electrically connected to the power line PL.

The light-emitting element LD is electrically connected between the first transistor T1 and the signal line SL. The signal line SL may provide a second power voltage ELVSS or a driving signal TDS to the cathode of the light-emitting element LD. The second power voltage ELVSS has a lower level than the first power voltage ELVDD.

The first transistor T1 is electrically connected between the power line PL and the anode of the light-emitting element LD. A source S1 of the first transistor T1 is electrically connected to the power line PL. In this specification, the expression “being electrically connected between a transistor and a signal line or between a transistor and a transistor” means “that the source, drain, and gate of the transistor have an integral shape with the signal line, or are connected through a connection electrode.” Another transistor may be located, or may not be located, between the source S1 of the first transistor T1 and the power line PL.

A drain D1 of the first transistor T1 is electrically connected to the anode of the light-emitting element LD. Another transistor may be located, or may not be located, between the drain D1 of the first transistor T1 and the anode of the light-emitting element LD. A gate G1 of the first transistor T1 is electrically connected to the reference node RN.

The second transistor T2 is electrically connected between the j-th data line DLj and the source S1 of the first transistor T1. A source S2 of the second transistor T2 is electrically connected to the j-th data line DLj, and a drain D2 of the second transistor T2 is electrically connected to the source S1 of the first transistor T1. In one or more embodiments, a gate G2 of the second transistor T2 may be electrically connected to the i-th scan line SLi of the first group.

The third transistor T3 is electrically connected between the reference node RN and the drain D1 of the first transistor T1. A drain D3 of the third transistor T3 is electrically connected to the drain D1 of the first transistor T1, and a source S3 of the third transistor T3 is electrically connected to the reference node RN. The third transistor T3 may include a plurality of gates G3. In one or more embodiments, a gate G3 of the third transistor T3 may be electrically connected to the i-th scan line GLi of the second group.

The fourth transistor T4 is electrically connected between the reference node RN and a first voltage line VL1. A drain D4 of the fourth transistor T4 is electrically connected to the reference node RN, and a source S4 of the fourth transistor T4 is electrically connected to the first voltage line VL1. The fourth transistor T4 may include a plurality of gates G4. In one or more embodiments, a gate G4 of the fourth transistor T4 may be electrically connected to the i-th scan line HLi of the third group.

The fifth transistor T5 is electrically connected between the power line PL and the source S1 of the first transistor T1. A source S5 of the fifth transistor T5 is electrically connected to the power line PL, and a drain D5 of the fifth transistor T5 is electrically connected to the source S1 of the first transistor T1. A gate G5 of the fifth transistor T5 may be electrically connected to an i-th light-emitting line ELi.

The sixth transistor T6 is electrically connected between the drain D1 of the first transistor T1 and the light-emitting element LD. A source S6 of the sixth transistor T6 is electrically connected to the drain D1 of the first transistor T1, and a drain D6 of the sixth transistor T6 is electrically connected to the anode of the light-emitting element LD. A gate G6 of the sixth transistor T6 may be electrically connected to the i-th light-emitting line ELi. In one or more embodiments of the present disclosure, the gate G6 of the sixth transistor T6 may be connected to the gate G5 of the fifth transistor T5 and another signal line.

The seventh transistor T7 is electrically connected between the drain D6 of the sixth transistor T6 and a second voltage line VL2. A source S7 of the seventh transistor T7 is electrically connected to the drain D6 of the sixth transistor T6, and a drain D7 of the seventh transistor T7 is electrically connected to the second voltage line VL2. A gate G7 of the seventh transistor T7 may be electrically connected to an (i+1)-th scan line SLi+1 of the first group.

However, FIG. 5 illustrates an equivalent circuit of the pixel PX only as an example, and details, such as the connection relationships and connection directions of the components of the pixel PX may be changed as suitable.

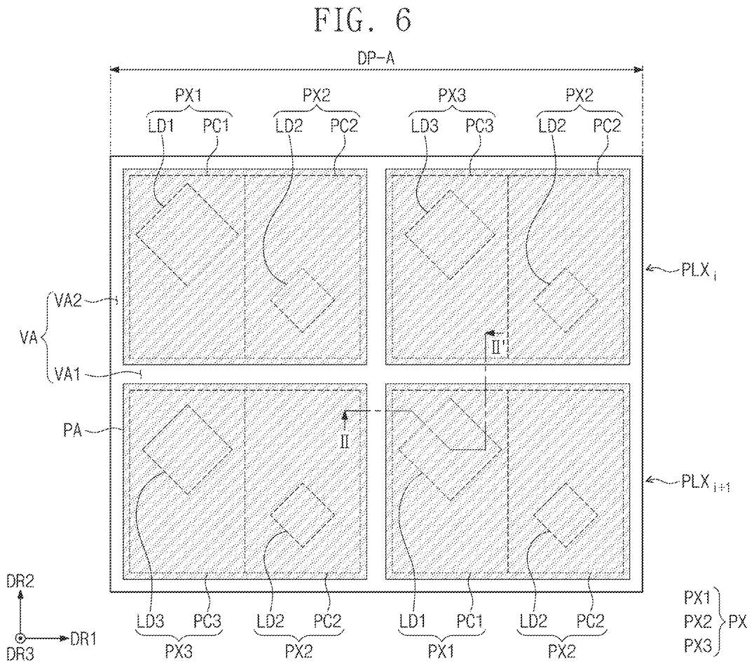

FIG. 6 is an enlarged plan view of a portion of a display region according to one or more embodiments of the present disclosure.

Referring to FIG. 6, pixels PX corresponding to two pixel rows PLXi and PLXi+1 of the display region DP-A are enlarged. The i-th pixel row PLXi may include a first color pixel PX1, a second color pixel PX2, a third color pixel PX3, and a second color pixel PX2, which are arranged in the first direction DR1. The (i+1)-th pixel row PLXi+1 may include a third color pixel PX3, a second color pixel PX2, a first color pixel PX1, and a second color pixel PX2, which are arranged in the first direction DR1.

The three color pixels of the pixel rows PLXi and PLXi+1 illustrated in FIG. 6 may be repeatedly located in the first direction DR1. The pixel rows PLXi and PLXi+1 may be repeatedly located in the second direction DR2. In FIG. 6, the anodes of a first light-emitting element LD1, a second light-emitting element LD2, and a third light-emitting element LD3, and a first pixel circuit PC1, a second pixel circuit PC2, and a third pixel circuit PC3, are illustrated as respective dotted lines.

The display region DP-A may include a plurality of pixel regions PA, and a boundary region VA adjacent to the plurality of pixel regions PA. The boundary region VA may be adjacent to at least a portion of each of the pixel regions PA. The boundary region VA may block external and internal impacts from being transmitted to the pixel regions PA.

Referring to FIG. 6, at least any one of the first color pixel PX1, the second color pixel PX2, or the third color pixel PX3 may be located in each pixel region PA. The pixel regions PA may be surrounded by the boundary region VA (e.g., in plan view). The boundary region VA may include a first boundary region VA1 extending in the first direction DR1, and a second boundary region VA2 extending in the second direction DR2.

The pixel circuits PC1, PC2, and PC3 respectively of the first to third color pixels PX1, PX2, and PX3 may be located in the plurality of pixel regions PA. Each of the pixel circuits PC1, PC2, and PC3 may be the pixel-driving circuit PC of FIG. 5. The arrangement of the pixel circuits PC1, PC2, PC3 and the pixel regions PA is not limited to the arrangement illustrated in FIG. 6.

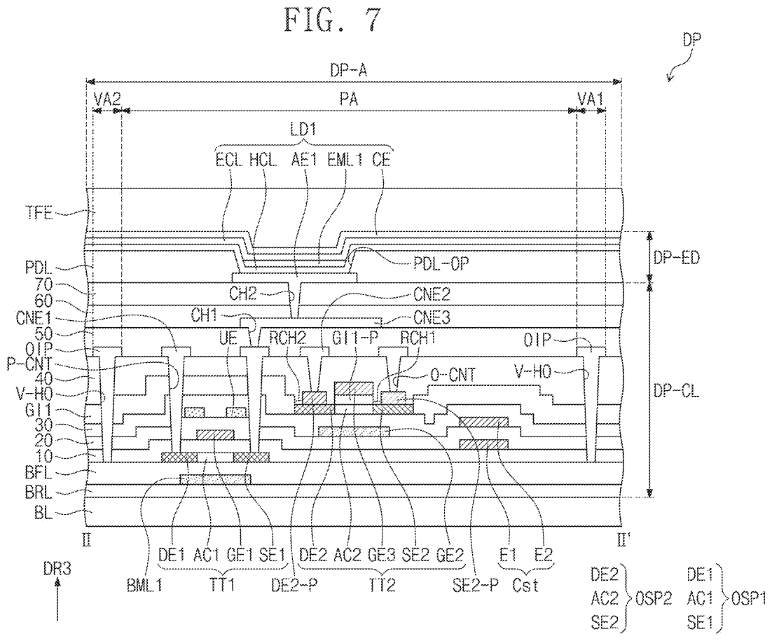

The pixel regions PA may be sufficiently defined as regions other than the boundary region VA in the display region DP-A. The boundary region VA is defined by a boundary opening V-HO (see FIG. 7) to be described later, and a region, which does not overlap the boundary opening V-HO (see FIG. 7), corresponds to the pixel region PA.

The arrangement of the pixel regions PA and the boundary region VA illustrated in FIG. 6 is only an example, and the arrangement of the pixel regions PA and the boundary region VA may be variously changed as suitable. For example, each of the first color pixel PX1, the second color pixel PX2, the third color pixel PX3, and the second color pixel PX2 may be surrounded by the boundary region VA.

FIG. 7 is a cross-sectional view taken along the line II-II′ of FIG. 6 according to one or more embodiments of the present disclosure.

FIG. 7 illustrates a first light-emitting element LD1, a first transistor TT1, and a second transistor TT2. The first transistor TT1 may be a silicon transistor, and the second transistor TT2 may be an oxide transistor. Here, the first transistor TT1 may be any one of the first, second, fifth, sixth, or seventh transistors T1, T2, T5, T6, or T7 of FIG. 5. The second transistor TT2 may be any one of the third or fourth transistors T3 or T4 of FIG. 5.

The base layer BL may overlap the pixel regions PA and the boundary region VA. The base layer BL may overlap not only the display region DP-A (see FIG. 2) of FIG. 2, but also the non-display region DP-NDA (see FIG. 2). FIG. 7 illustrates one pixel region among the plurality of pixel regions PA, the first boundary region VA1, and the second boundary region VA2 adjacent to the first boundary region VA1.

A plurality of inorganic layers BRL and BFL may be located on the base layer BL. The inorganic layers BRL and BFL may include a barrier layer BRL and a buffer layer BFL. Like the base layer BL, the inorganic layers BRL and BFL may overlap not only the display region DP-A (see FIG. 2), but also the non-display region DP-NDA (see FIG. 2).

The barrier layer BRL may reduce or prevent foreign substances from entering from the outside. The barrier layer BRL may include at least one inorganic layer. The barrier layer BRL may include a silicon oxide layer and a silicon nitride layer. Each of these may be provided in plurality, and silicon oxide layers and silicon nitride layers may be alternately stacked.

A first back surface metal pattern BML1 may be located on the barrier layer BRL. The first back surface metal pattern BML1 may include metal. The first back surface metal pattern BML1 may include molybdenum (Mo) having good heat resistance, an alloy containing molybdenum, titanium (Ti), or an alloy containing titanium. The first back surface metal pattern BML1 may receive a bias voltage. The first back surface metal pattern BML1 may receive the driving voltage ELVDD (see FIG. 5). The first back surface metal pattern BML1 may block an electric potential due to a polarization phenomenon from affecting the first transistor TT1. The first back surface metal pattern BML1 may block external light from reaching the first transistor TT1.

The buffer layer BFL may be located on the barrier layer BRL. The buffer layer BFL may cover the first back surface metal pattern BML1. The buffer layer BFL may reduce or prevent metal atoms or impurities from diffusing from the base layer BL into a first semiconductor pattern OSP1. The buffer layer BFL may include at least one inorganic layer. The buffer layer BFL may include a silicon oxide layer and a silicon nitride layer.

The first semiconductor pattern OSP1 may be located on the buffer layer BFL. The first semiconductor pattern OSP1 may include a silicon semiconductor. For example, the silicon semiconductor may include amorphous silicon, polycrystalline silicon, and the like. For example, the first semiconductor pattern OSP1 may include low-temperature poly (polycrystalline) silicon.

The first semiconductor pattern OSP1 may have different electrical properties depending on whether it is doped or not. The first semiconductor pattern OSP1 may include a first region having high conductivity and a second region having low conductivity. The first region may be doped with an N-type dopant or a P-type dopant. A P-type transistor may include a doped region doped with a P-type dopant, and an N-type transistor may include a doped region doped with an N-type dopant. The second region may be a non-doped region or a region doped with a lower concentration than the first region.

The conductivity of the first region may be greater than that of the second region, and the first region may substantially serve as an electrode or a signal line. The second region may substantially correspond to a channel region (or active region) of a transistor. In other words, a portion of the first semiconductor pattern OSP1 may be a channel of a transistor, another portion thereof may be a source or drain of a transistor, and still another portion thereof may be a connection electrode or a connection signal line.

A first source SE1, a first active region AC1, and a first drain DE1 of the first transistor TT1 may be formed from the first semiconductor pattern OSP1. The first source SE1 and the first drain DE1 may extend in opposite directions from each other from the first active region AC1 on a cross section.

A plurality of insulating layers 10, 20, 30, 40, 50, 60, 70, and GI1 may be located on the plurality of inorganic layers BRL and BFL. A first insulating layer 10 may be located on the buffer layer BFL. The first insulating layer 10 may cover the first semiconductor pattern OSP1. The first insulating layer 10 may include at least one of aluminum oxide, titanium oxide, silicon oxide, silicon nitride, silicon oxynitride, zirconium oxide, or hafnium oxide.

The first insulating layer 10 may be a single-layered silicon oxide layer. The plurality of insulating layers 10, 20, 30, 40, 50, 60, 70, and GI1 may have a single-layered or multi-layered structure, and may include at least one of the above-mentioned materials, but the present disclosure is not limited thereto.

The first electrode E1 of the capacitor Cst may be located on the first insulating layer 10. In addition, a first gate GE1 may be located on the first insulating layer 10.

A second insulating layer 20 may be located on the first insulating layer 10 and may cover the first gate GE1. The first gate GE1 may correspond to the first active region AC1. An upper electrode UE may be located on the second insulating layer 20. The second electrode E2 overlapping the first electrode E1 of the capacitor Cst may be located on the second insulating layer 20. The second electrode E2 and the upper electrode UE may include molybdenum (Mo) having good heat resistance, an alloy containing molybdenum, titanium (Ti), or an alloy containing titanium.

A second gate GE2 may be located on the second insulating layer 20. The second gate GE2 may be located to correspond to a lower portion of the second transistor TT2.

A third insulating layer 30 may be located on the second insulating layer 20. The third insulating layer 30 may cover the upper electrode UE, the second gate GE2 (or lower gate), and the second electrode E2.

FIG. 7 illustrates that the second gate GE2 is located on the second insulating layer 20, but the arrangement of the second gate GE2 is not limited thereto. For example, the second gate GE2 may be located on the same layer as the first gate GE1, and may include the same material as the first gate GE1. In this case, the second gate GE2 may be substituted with the first gate GE1.

For example, the second gate GE2 may be located on the same layer as the first back surface metal pattern BML1, and may include the same material as the first back surface metal pattern BML1. In this case, the second gate GE2 may be substituted with the first back surface metal pattern BML1.

A second semiconductor pattern OSP2 may be located on the third insulating layer 30. The second semiconductor pattern OSP2 may include an oxide semiconductor. The second semiconductor pattern OSP2 may include a transparent conductive oxide (TCO), such as indium tin oxide (ITO), indium zinc oxide (IZO), indium gallium zinc oxide (IGZO), zinc oxide (ZnOx), or indium oxide (In₂O₃).

A second source SE2, a second active region AC2, and a second drain DE2 of the second transistor TT2 may be formed from the second semiconductor pattern OSP2. The second source SE2 and the second drain DE2 may extend in opposite directions from each other from the second active region AC2 on a cross section.

The oxide semiconductor may include a plurality of regions divided according to whether or not the transparent conductive oxide is reduced. A region in which the transparent conductive oxide is reduced (hereinafter referred to as a reduced region) has higher conductivity than a region in which the transparent conductive oxide is not reduced (hereinafter referred to as a non-reduced region). The reduced region substantially serves as a source/drain of a transistor or a signal line. The non-reduced region substantially corresponds to a semiconductor region (or channel) of a transistor. In other words, a portion of the second semiconductor pattern OSP2 may be a semiconductor region of a transistor, another portion thereof may be a source/drain region of a transistor, and still another portion thereof may be a signal transmission region.

A portion GI1-P of a gate-insulating layer may be located on the second active region AC2. The portion GI1-P of the gate-insulating layer may be positioned between a third gate GE3, which will be described later, and the second semiconductor pattern OSP2. The portion GI1-P of the gate-insulating layer may overlap the third gate GE3 on a plane. The portion GI1-P of the gate-insulating layer may come in contact with the upper surface of the second active region AC2 and the lower surface of the third gate GE3.

The third gate GE3 (or upper gate) may be located on the portion GI1-P of the gate-insulating layer. The third gate GE3 may be located above the second semiconductor pattern OSP2, and may correspond to the second active region AC2. The third gate GE3 may be a portion of a metal pattern. The third gate GE3 may overlap the second active region AC2 of the second transistor TT2. The third gate GE3 may include molybdenum (Mo) having good heat resistance, an alloy containing molybdenum, titanium (Ti), or an alloy containing titanium. The third gate GE3 may include a titanium layer and a molybdenum layer located on the titanium layer.

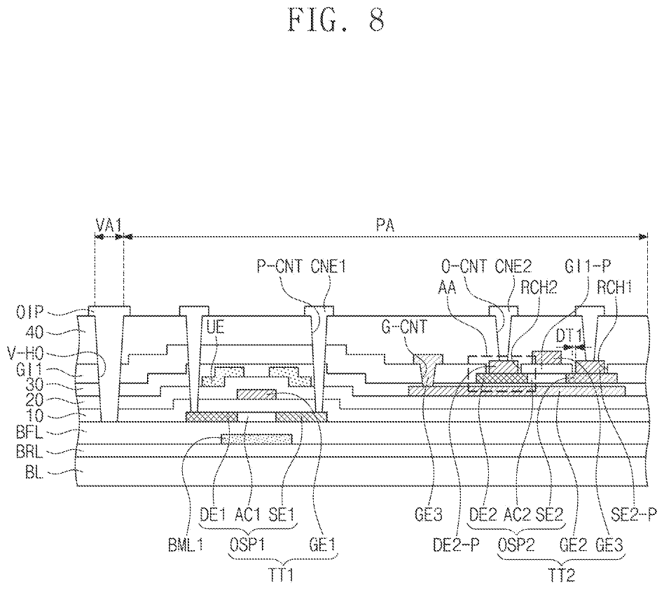

The third gate GE3 may be connected to the second gate GE2 through a contact hole. This will be described later with reference to FIG. 8.

A gate-insulating layer GI1 may be located on the third insulating layer 30. The gate-insulating layer GI1 may cover the second active region AC2. A first opening RCH1 corresponding to the second source SE2, and a second opening RCH2 overlapping the second drain DE2, may be defined in the gate-insulating layer GI1.

A first protective pattern SE2-P may be located in the first opening RCH1 and may be located on the second source SE2. The first protective pattern SE2-P may include the same material as the third gate GE3, and may be formed in the same process as the third gate GE3. On a cross section, the width of the first protective pattern SE2-P may be less than that of the first opening RCH1.

A second protective pattern DE2-P may be located in the second opening RCH2, and may be located on the second drain DE2. The second protective pattern DE2-P includes the same material as the third gate GE3, and may be formed in the same process as the third gate GE3. On a cross section, the width of the second protective pattern DE2-P may be less than that of the second opening RCH2.

A fourth insulating layer 40 may be located on the gate-insulating layer GI1. The fourth insulating layer 40 may cover the first protective pattern SE2-P, the second protective pattern DE2-P, and the third gate GE3. Each of the first to fourth insulating layers 10, 20, 30, and 40 and the gate-insulating layer GI1 may be an inorganic layer.

A boundary opening V-HO may be defined in the first to fourth insulating layers 10, 20, 30, and 40. The boundary opening V-HO may correspond to the boundary region VA (see FIG. 6) described with reference to FIG. 6, and the boundary opening V-HO may form a valley in the display panel DP. The boundary opening V-HO located on the right side of FIG. 7 may correspond to the first boundary region VA1 (see FIG. 6), and the boundary opening V-HO located on the left side of FIG. 7 may correspond to the second boundary region VA2 (see FIG. 6). The boundary opening V-HO may expose the upper surface of the buffer layer BFL.

The first to fourth insulating layers 10, 20, 30, and 40 and the gate-insulating layer GI1 may be divided into a plurality of islands so as to correspond to the plurality of pixels PX1, PX2, and PX3 illustrated in FIG. 6. As an impact applied from the outside may be concentrated on the boundary opening V-HO, it is possible to reduce or prevent the likelihood of a crack occurring in the first to fourth insulating layers 10, 20, 30, and 40 and the gate-insulating layer GI1. In addition, the boundary opening V-HO may reduce or prevent the likelihood of a crack being generated in a specific pixel region from extending to an adjacent pixel region.

An organic pattern OIP may be located inside the boundary opening V-HO. The organic pattern OIP may come in contact with an inner side surface of each of the first to fourth insulating layers 10, 20, 30, and 40 and the gate-insulating layer GI1 located in, and defining, the boundary opening V-HO. The organic pattern OIP may be formed of a material having a lower elastic modulus than that of the fifth insulating layer 50. The organic pattern OIP may reduce the defects of the display panel DP by absorbing an impact concentrated on the boundary opening V-HO.

A fifth insulating layer 50 may be located on the fourth insulating layer 40. A first connection electrode CNE1 may be connected to at least one of the first drain DE1 or the first source SE1 of the first transistor TT1 through a second contact hole P-CNT passing through the first to fourth insulating layers 10, 20, 30, and 40 and the gate-insulating layer GI1.

A second connection electrode CNE2 may be connected to at least one of the second drain DE2 or the second source SE2 of the second transistor T2 through a third contact hole O-CNT passing through the fourth insulating layer 40.

A fifth insulating layer 50 may be located on the fourth insulating layer 40. The fifth insulating layer 50 may remove a step difference formed in the lower insulating layers 10, 20, 30, 40, and GI1, and may provide a flat upper surface. The fifth insulating layer 50 may cover the first connection electrode CNE1, the second connection electrode CNE2, and the organic pattern OIP. A third connection electrode CNE3 may be located on the fifth insulating layer 50. The third connection electrode CNE3 may be connected to the first connection electrode CNE1 through a first through hole CH1 passing through the fifth insulating layer 50.

A sixth insulating layer 60 may be located on the fifth insulating layer 50. The sixth insulating layer 60 may cover the third connection electrode CNE3. A seventh insulating layer 70 may be located on the sixth insulating layer 60.

Each of the fifth to seventh insulating layers 50, 60, and 70 may be an organic layer. For example, each of the fifth to seventh insulating layers 50, 60, and 70 may include a general-purpose polymer, such as benzocyclobutene (BCB), polyimide, hexamethyldisiloxane (HMDSO), polymethylmethacrylate (PMMA), or polystyrene (PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and blends thereof.

A first anode AE1 of the first light-emitting element LD1 may be located on the seventh insulating layer 70. The first anode AE1 may be connected to the third connection electrode CNE3 through a second through hole CH2 passing through the sixth insulating layer 60 and the seventh insulating layer 70. The first light-emitting element LD1 may include a first anode AE1, a first light-emitting layer EML1, and a cathode CE. The cathode CE may be provided in common to the first light-emitting element LD1, the second light-emitting element LD2 (see FIG. 6), and the third light-emitting element LD3 (see FIG. 6).

The first anode AE1 may be a transparent electrode, a semi-transparent electrode, or a reflective electrode. According to one or more embodiments of the present disclosure, the first anode AE1 may include a reflective layer formed of Ag, Mg, Al, Pt, Pd, Au, Ni, Nd, Ir, Cr, or compounds thereof, and a transparent or semi-transparent electrode layer formed on the reflective layer. The transparent or semi-transparent electrode layer may contain at least one selected from a group consisting of an indium tin oxide (ITO), an indium zinc oxide (IZO), an indium gallium zinc oxide (IGZO), a zinc oxide (ZnOx), an indium oxide (In₂O₃), or an aluminum-doped zinc oxide (AZO). For example, the first anode AE1 may include a stacked structure of ITO/Ag/ITO.

A pixel-defining film PDL may be located on the seventh insulating layer 70. The pixel-defining film PDL may have transparent properties or light-absorbing properties. For example, the pixel-defining film PDL that absorbs light may include a black coloring agent. The black coloring agent may include a black dye and a black pigment. The black coloring agent may include carbon black, a metal, such as chromium, or an oxide thereof. The pixel-defining film PDL may correspond to a light-blocking pattern having light-blocking properties.

The pixel-defining film PDL may cover a portion of the first anode AE1. For example, an opening PDL-OP exposing the portion of the first anode AE1 may be defined in the pixel-defining film PDL. The pixel-defining film PDL may increase the distance between an edge of the first anode AE1 and the cathode CE. Accordingly, the pixel-defining film PDL may serve to reduce or prevent the likelihood of an arc or the like occurring at the edge of the first anode AE1.

A hole control layer HCL may be located between the first anode AE1 and the first light-emitting layer EML1. The hole control layer HCL may include a hole transport layer and a hole injection layer. An electron control layer ECL may be located between the first light-emitting layer EML1 and the cathode CE. The electron control layer ECL may include an electron transport layer and an electron injection layer. The hole control layer HCL and the electron control layer ECL may be commonly formed in the plurality of pixel rows PLXi and PLXi+1 (see FIG. 6) by using an open mask.

An encapsulation layer TFE may be located on the first light-emitting element LD1. The encapsulation layer TFE may include an encapsulation inorganic layer and an encapsulation organic layer, which are sequentially stacked. A plurality of encapsulation inorganic layers and a plurality of encapsulation organic layers may be alternately located with each other. However, the layers constituting the encapsulation layer TFE are not limited thereto and may have various arrangements.

The encapsulation inorganic layer may protect the first light-emitting element LD1 from moisture and oxygen, and the encapsulation organic layer may protect the first light-emitting element LD1 from foreign substances, such as dust particles.

FIG. 8 is a cross-sectional view of a base layer and a circuit layer according to one or more embodiments of the present disclosure. Unlike FIG. 7, FIG. 8 illustrates a structure in which the second gate GE2 and the third gate GE3 are connected to each other through a first contact hole G-CNT. Other than that, the same reference numerals are used for the same components as those illustrated in FIG. 7, and the descriptions thereof are omitted.

The third gate GE3 illustrated on the left side of FIG. 8 may be electrically connected to the second gate GE2 through the first contact hole G-CNT passing through the third insulating layer 30 and the gate-insulating layer GI1. In the cross-sectional view, the third gate GE3 illustrated on the left side of FIG. 8 and the third gate GE3 overlapping the second active region AC2 illustrated on the right side thereof are illustrated to be spaced apart from each other, but they may be electrically connected to each other on a plane.

The second gate GE2 and the third gate GE3 may be the dual gates of the second transistor TT2 that is an oxide transistor. Because the second gate GE2 and the third gate GE3 are electrically connected to each other, the same signal may be applied to each other concurrently or substantially simultaneously. In addition, although only one of the second gate GE2 or the third gate GE3 extends along the signal lines HLi and GLi (see FIG. 5), a signal may be applied to both the second gate GE2 and the third gate GE3. Accordingly, this case takes up less space than a case in which both the second gate GE2 and the third gate GE3 extend along the signal lines HLi and GLi (see FIG. 5) and, therefore, restrictions on resolution layout may be reduced.

Although FIG. 8 illustrates that the second gate GE2 is located on the second insulating layer 20, the arrangement of the second gate GE2 is not limited thereto.

For example, the second gate GE2 may be located on the same layer as the first gate GE1, and may include the same material as the first gate GE1. In this case, the third gate GE3 may be electrically connected to the second gate GE2 through the first contact hole G-CNT passing through the second insulating layer 20, the third insulating layer 30, and the gate-insulating layer GI1.

For example, the second gate GE2 may be located on the same layer as the first back surface metal pattern BML1, and may include the same material as the first back surface metal pattern BML1. In this case, the third gate GE3 may be electrically connected to the second gate GE2 through the first contact hole G-CNT passing through the buffer layer BFL, the first to third insulating layers 10, 20, and 30, and the gate-insulating layer GI1.

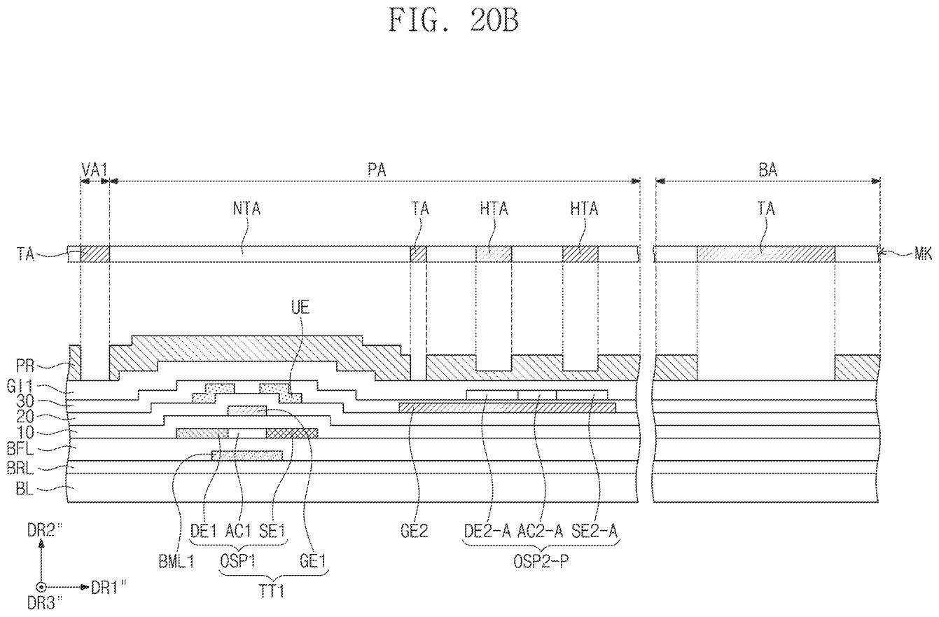

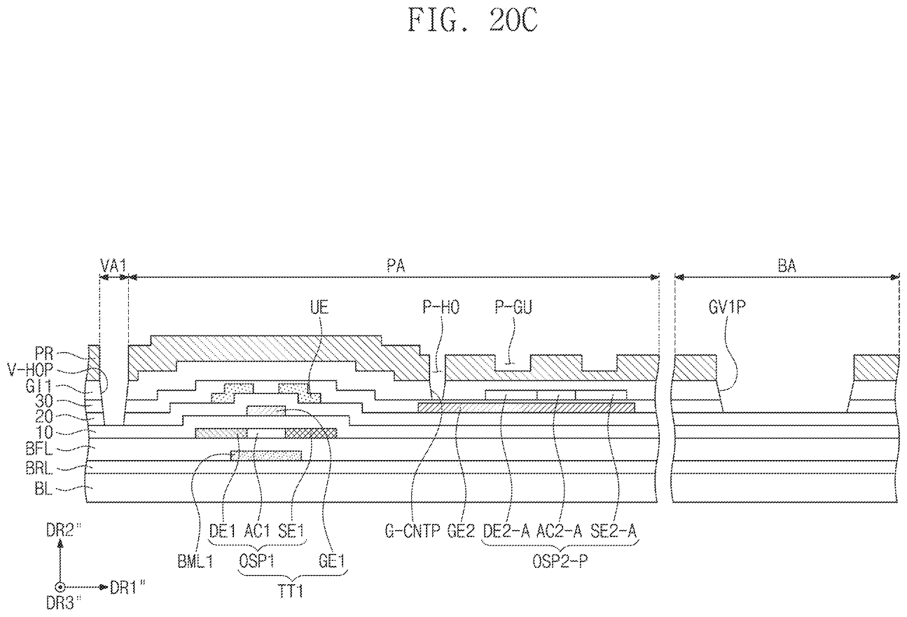

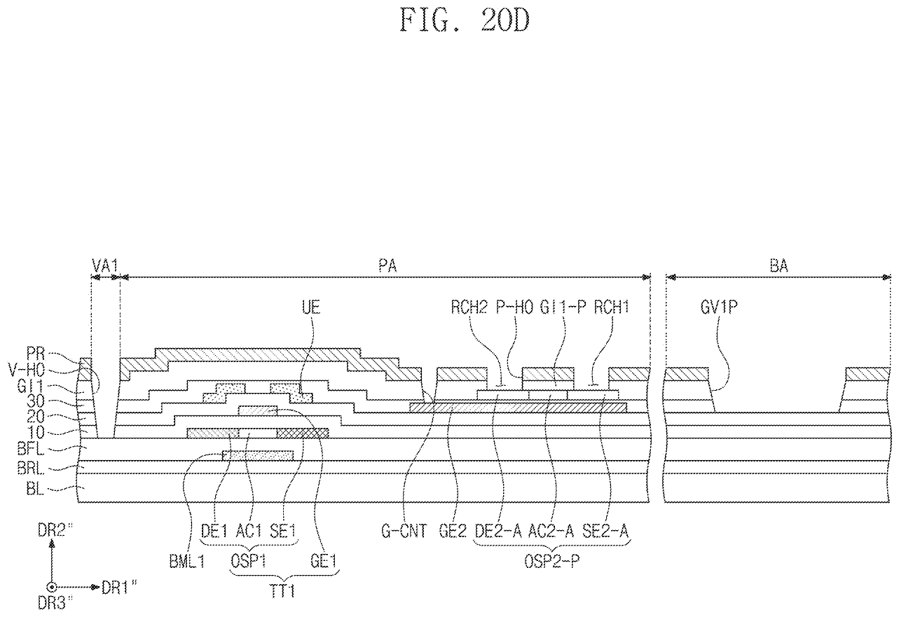

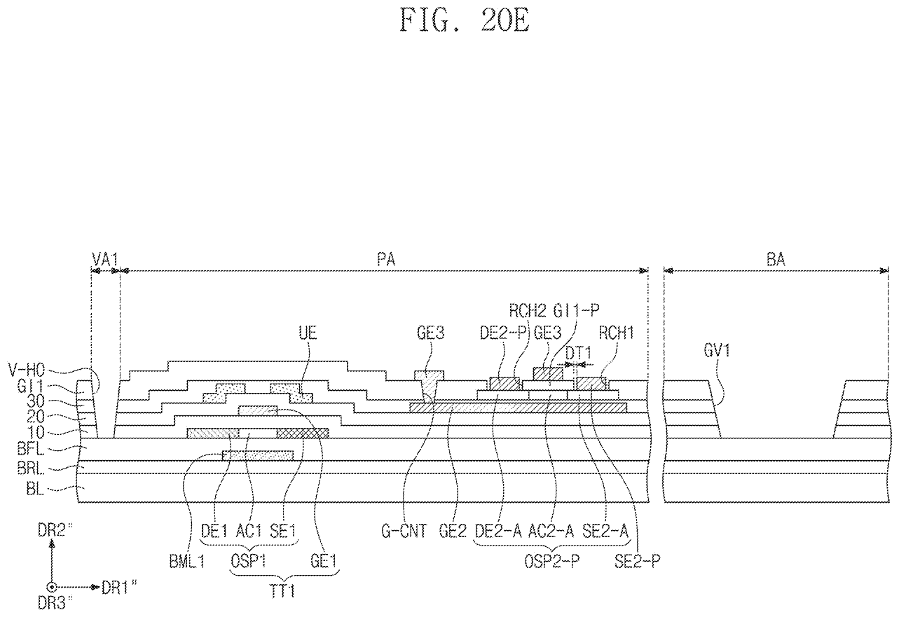

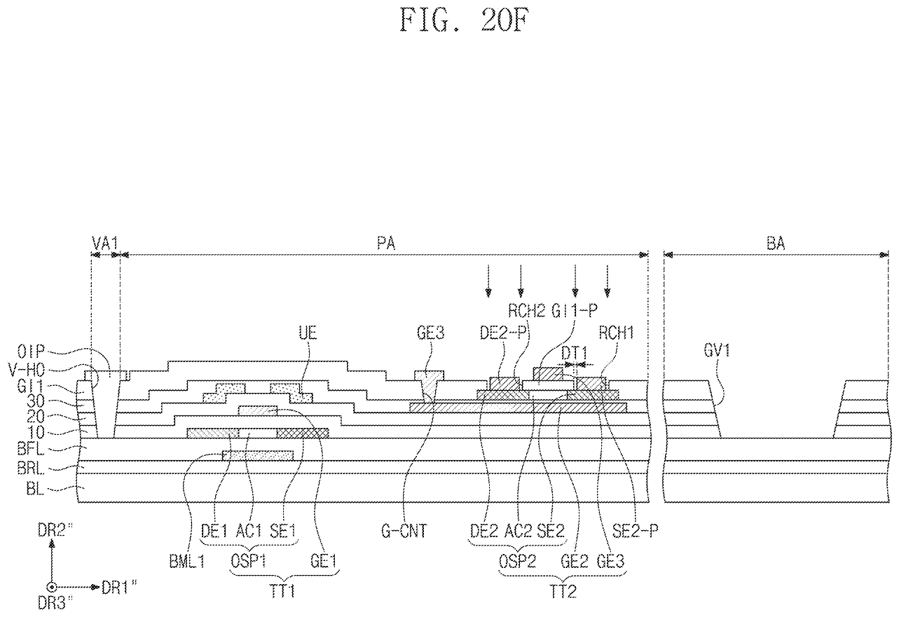

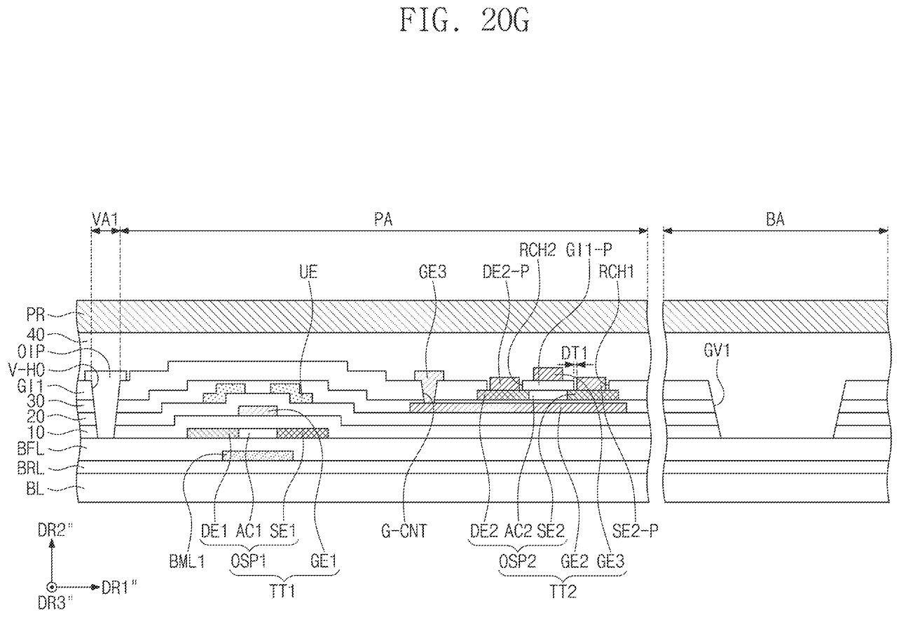

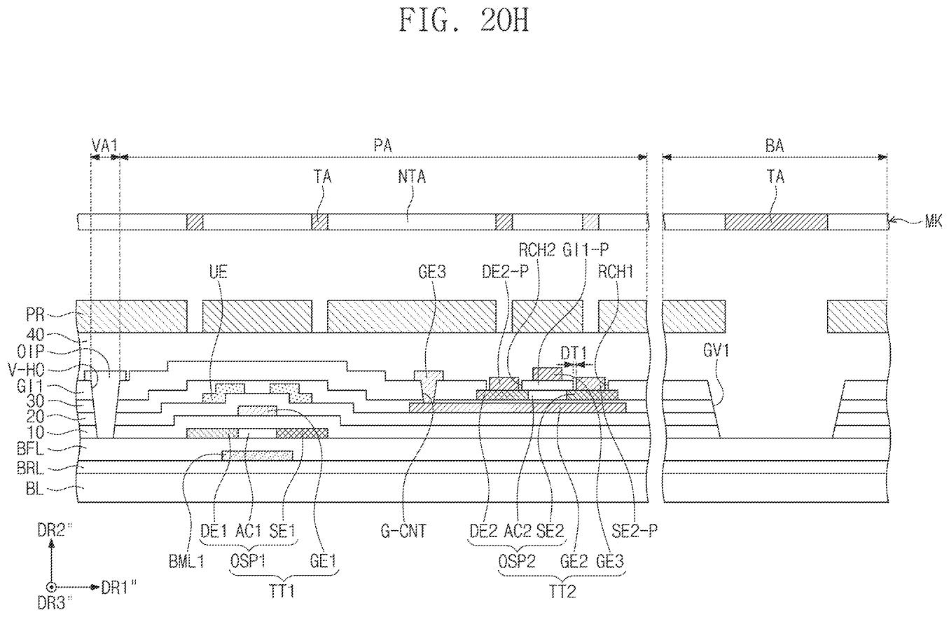

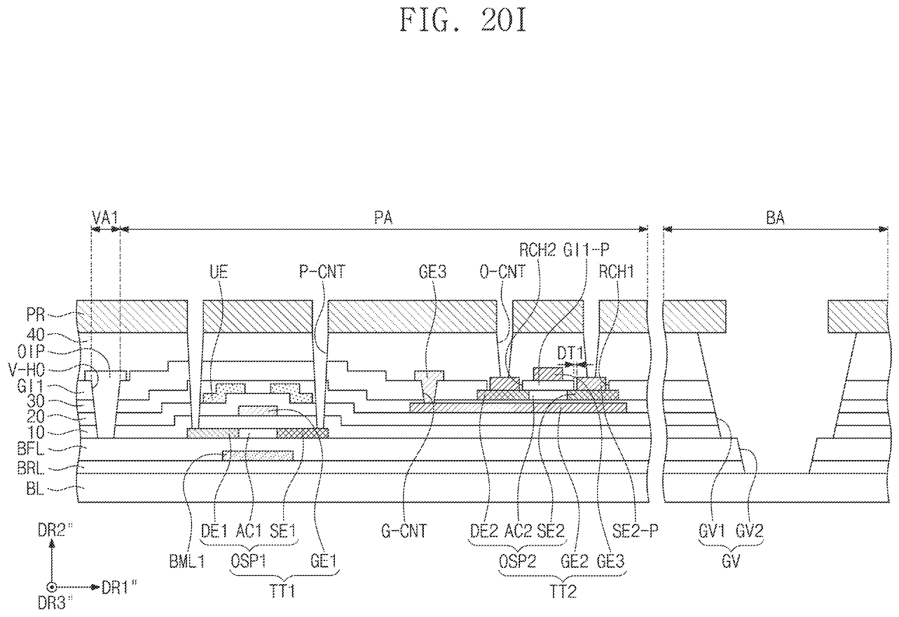

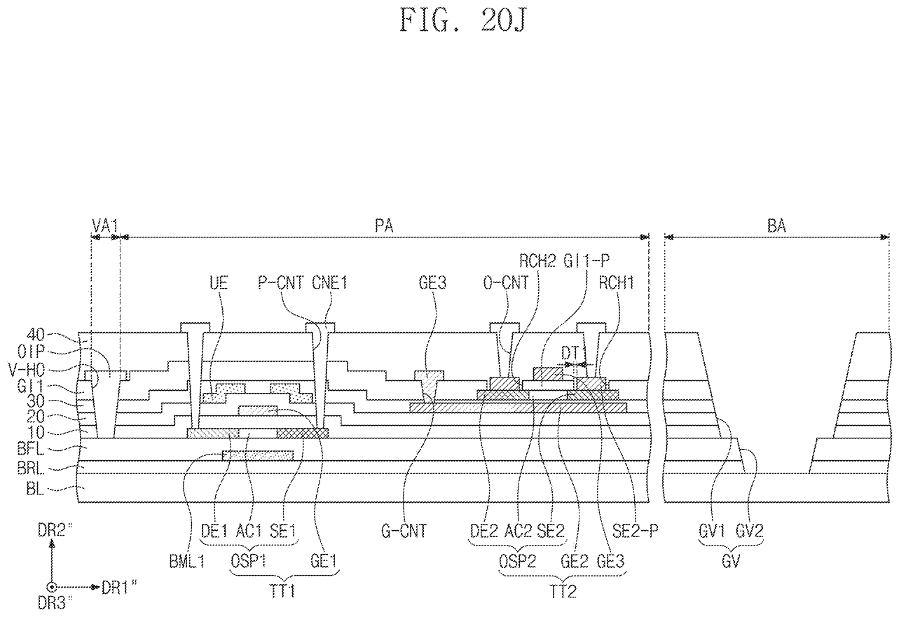

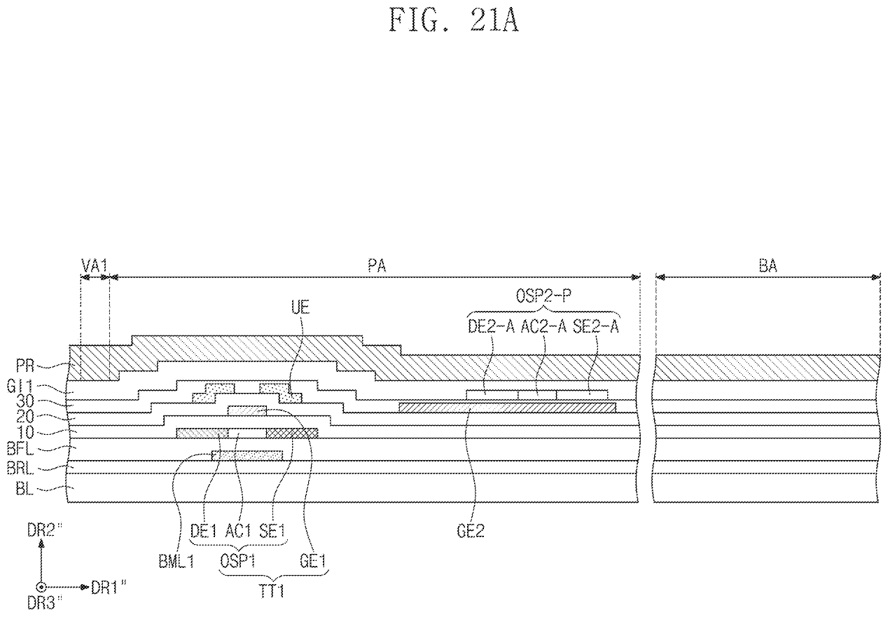

Each of the first and second protective patterns SE2-P and DE2-P may be spaced apart from the inner side surfaces of the gate-insulating layer GI1 defining the first opening RCH1 and the second opening RCH2 at a distance (e.g., predetermined distance) DT1. Accordingly, a process of doping the second source SE2 and the second drain DE2 may be performed smoothly. This will be described later with reference to FIG. 20F.

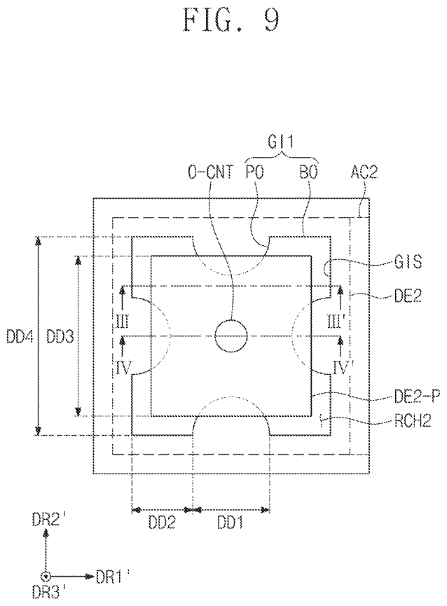

FIG. 9 is a plan view of a portion AA of FIG. 8 according to one or more embodiments of the present disclosure.

FIG. 9 illustrates one or more embodiments of the present disclosure in which the shape of the second opening RCH2 and the arrangement of the second protective pattern DE2-P are illustrated. Hereinafter, the shape of the first opening RCH1 (see FIG. 8) and the arrangement of the first protective pattern SE2-P (see FIG. 8) may be equally applied to the shape of the second opening RCH2 and the arrangement of the second protective pattern DE2-P in FIG. 9 and, therefore, a repeated description thereof will not be described separately. First to third directions DR1′, DR2′, and DR3′ of FIG. 9 may be distinct from, and may not be the same as, the previously mentioned first to third directions DR1, DR2, and DR3.

The second opening RCH2 overlapping the second drain DE2 may be defined in the gate-insulating layer GI1. A width DD4 of the second opening RCH2 in the second direction DR2′ may be greater than a width DD3 of the second protective pattern DE2-P in the second direction DR2′. For example, the width DD4 of the second opening RCH2 in the second direction DR2′ may be about 5 μm to about 7 μm. The width DD3 of the second protective pattern DE2-P in the second direction DR2′ may range from about 4.5 μm to about 6.5 μm. A width of the second opening RCH2 in the first direction DR1′ may be equal to the width DD4 in the second direction DR2′, and a width of the second protective pattern DE2-P in the first direction DR1′ may be equal to the width DD3 in the second direction DR2′, but the present disclosure is not limited thereto, and they may be different from each other and are not particularly limited.

In one or more embodiments of the present disclosure, the area of the second opening RCH2 on a plane may be greater than or equal to the area of the second protective pattern DE2-P, but the present disclosure is not particularly limited.

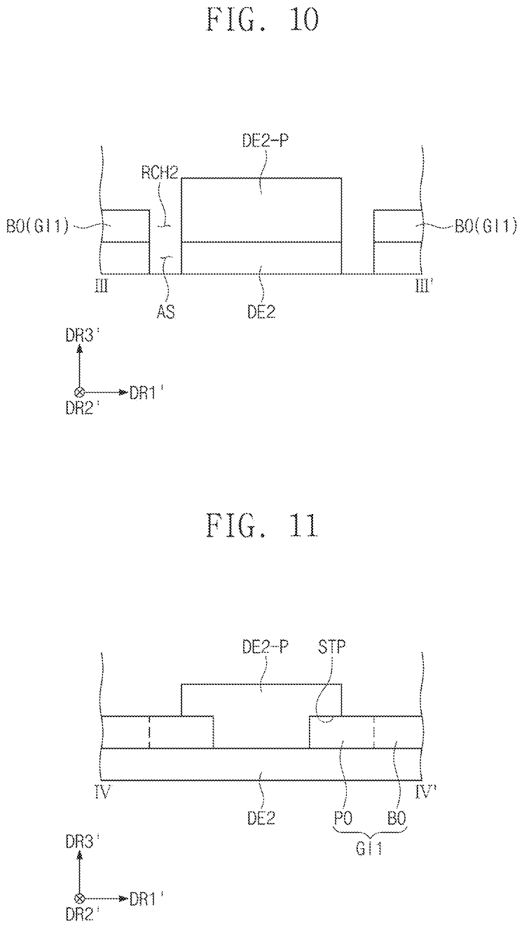

A portion of the second protective pattern DE2-P may overlap the gate-insulating layer GI1, and the remaining portion of the second protective pattern DE2-P may not overlap the gate-insulating layer GI1. The gate-insulating layer GI1 may include an insulating body BO and an insulating protrusion portion PO protruding from the insulating body BO. The insulating protrusion portion PO may be defined on an inner side surface GIS of the gate-insulating layer GI1 defining the second opening RCH2. At least a portion of the insulating protrusion portion PO may overlap a portion of the second protective pattern DE2-P. Like this, as a portion of the insulating protrusion portion PO overlaps a portion of the second protective pattern DE2-P, it is possible to reduce or prevent the likelihood of electricity not flowing through the second drain DE2 due to a portion of the second drain DE2, which does not overlap the gate-insulating layer GI1 and the protective patterns DE2-P and SE2-P, being damaged. This will be described later with reference to FIGS. 10 and 11.

The insulating protrusion portions PO may be spaced apart from each other at regular intervals along the inner side surface GIS. Although FIG. 9 illustrates that four insulating protrusion portions PO are located to be spaced apart from each other along the inner side surface GIS at regular intervals, the number of the insulating protrusion portions PO may be changed as suitable. For example, it is possible to increase the number of the insulating protrusion portions PO to increase the number of portions of the second drain DE2 (e.g., portions of the second drain DE2 corresponding to the insulating protrusion portion PO) through which current flows.

The insulating protrusion portion PO may protrude from the insulating body BO in the first direction DR1′ or in the second direction DR2′. A width DD1 of the insulating protrusion portion PO in the first direction DR1′ may range from about 1 μm to about 2 μm. A width DD2 of the inner side surface GIS in the first direction DR1′, in which a protrusion portion is not defined, may be about 1.5 μm to about 2.5 μm. A width of the insulating protrusion portion PO in the second direction DR2′ may be the same as the width DD1 in the first direction DR1′, but the present disclosure is not limited thereto, and they may be different from each other and the present disclosure is not particularly limited.

The third contact hole O-CNT may come in contact with the upper surface of the second protective pattern DE2-P. When the second protective pattern DE2-P is not present, the second drain DE2 may be damaged in a process of forming the third contact hole O-CNT. That is, because the second protective pattern DE2-P covers the second drain DE2 overlapping a portion in which the third contact hole O-CNT is formed, it is possible to reduce or prevent damage to the second drain DE2 in the process of forming the third contact hole O-CNT.

A portion of the second drain DE2, which is not covered by the gate-insulating layer GI1 and the second protective pattern DE2-P, may be exposed to the outside during a manufacturing process. Like this, doping may be performed through the externally exposed portion of the second drain DE2. However, the externally exposed portion of the second drain DE2 may be damaged in a patterning process of the second protective pattern DE2-P.

FIG. 10 is a cross-sectional view taken along the line III-III′ of FIG. 9 according to one or more embodiments of the present disclosure.

FIG. 10 illustrates a cross section of a region corresponding to a portion of the inner side surface GIS (see FIG. 9) in which the insulating protrusion portion PO (see FIG. 9) is not defined. According to FIG. 10, there may be a portion of the second drain DE2 exposed to the outside through the second opening RCH2 during a manufacturing process. Damage AS may occur in a portion of the second drain DE2 that is not protected by the gate-insulating layer GI1 and the second protective pattern DE2-P. The portion of the second drain DE2 that is not protected by the gate-insulating layer GI1 and the second protective pattern DE2-P may be damaged AS in a process of patterning the second protective pattern DE2-P. Electricity may not flow in a portion disconnected due to the damage AS to the second drain DE2. Accordingly, as illustrated in FIG. 11, a portion, in which the damage AS of the second drain DE2 does not occur, may suitably remain.

FIG. 11 is a cross-sectional view taken along the line IV-IV′ of FIG. 9 according to one or more embodiments of the present disclosure.

FIG. 11 illustrates a cross section of a region corresponding to a portion of the inner side surface GIS (see FIG. 9) in which the insulating protrusion portion PO is defined. According to FIG. 11, a portion of the insulating protrusion portion PO of the gate-insulating layer GI1 may overlap the second protective pattern DE2-P. A step difference STP corresponding to the second protective pattern DE2-P may be defined in the gate-insulating layer GI1. Because the insulating protrusion portion PO of the gate-insulating layer GI1 overlaps the second protective pattern DE2-P, a portion of the second drain DE2 covered by the insulating protrusion portion PO of the gate-insulating layer GI1 may not be exposed to the outside during a manufacturing process. Accordingly, damage AS (see FIG. 10) may not occur in the second drain DE2. Although the second drain DE2 is damaged as illustrated in FIG. 10, current may flow through a portion of the second drain DE2 that is not damaged as illustrated in FIG. 11.

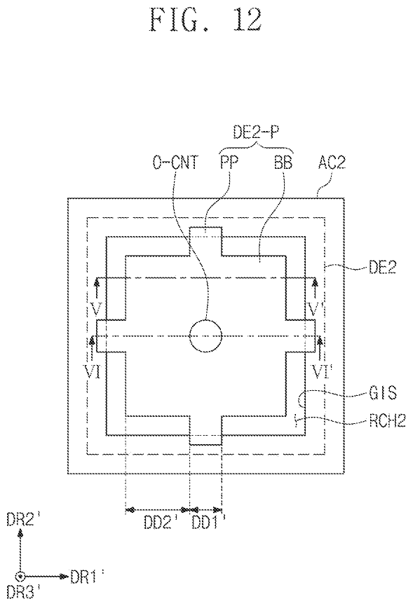

FIG. 12 is a plan view of the portion AA of FIG. 8 according to one or more embodiments of the present disclosure. FIG. 12 illustrates one or more embodiments different from that of FIG. 9. Hereinafter, descriptions of the same components as those described in FIG. 9 will be omitted.

FIG. 12 illustrates one or more embodiments of the shape of the second opening RCH2 and the arrangement of the second protective pattern DE2-P. Hereinafter, as the shape of the second opening RCH2 and the arrangement of the second protective pattern DE2-P in FIG. 12 are equal to the shape of the first opening RCH1 (see FIG. 8) and the arrangement of the first protective pattern SE2-P (see FIG. 8), they will not be described separately.

The second protective pattern DE2-P may include a protective pattern body BB and a protective pattern protrusion portion PP protruding from the protective pattern body BB. The protective pattern protrusion portion PP may protect the second drain DE2 located therebelow during a patterning process of the second protective pattern DE2-P.

A portion of the protective pattern protrusion portion PP, which is a portion of the second protective pattern DE2-P, may overlap the gate-insulating layer GI1, and the remaining portion of the protective pattern protrusion portion PP and the protective pattern body BB may not overlap the gate-insulating layer GI1.

The protective pattern protrusion portion PP may be provided in plurality, and the plurality of protective pattern protrusion portions PP may be spaced apart from each other along an outer side surface of the second protective pattern DE2-P. Although FIG. 12 illustrates that four protective pattern protrusion portions PP are located to be spaced apart from each other at regular intervals along the outer side surface of the second protective pattern DE2-P, the number of the protective pattern protrusion portions PP may be changed as suitable.

A width DD1′ of the protective pattern protrusion portion PP in the first direction DR1′ may be about 1.5 μm to about 2.5 μm. A width DD2′ of the protective pattern body BB in the first direction DR1′, in which the protective pattern protrusion portion PP is not defined, may be about 1 μm to about 2 μm.

FIG. 13 is a cross-sectional view taken along the line V-V′ of FIG. 12 according to one or more embodiments of the present disclosure.

FIG. 13 illustrates a cross section of a region corresponding to a portion of the second protective pattern DE2-P in which the protective pattern protrusion portion PP is not defined. According to FIG. 13, there may be a portion of the second drain DE2 exposed to the outside through the second opening RCH2 during a manufacturing process. Damage AS may occur in the portion of the second drain DE2 that is not protected by the gate-insulating layer GI1 and the second protective pattern DE2-P.

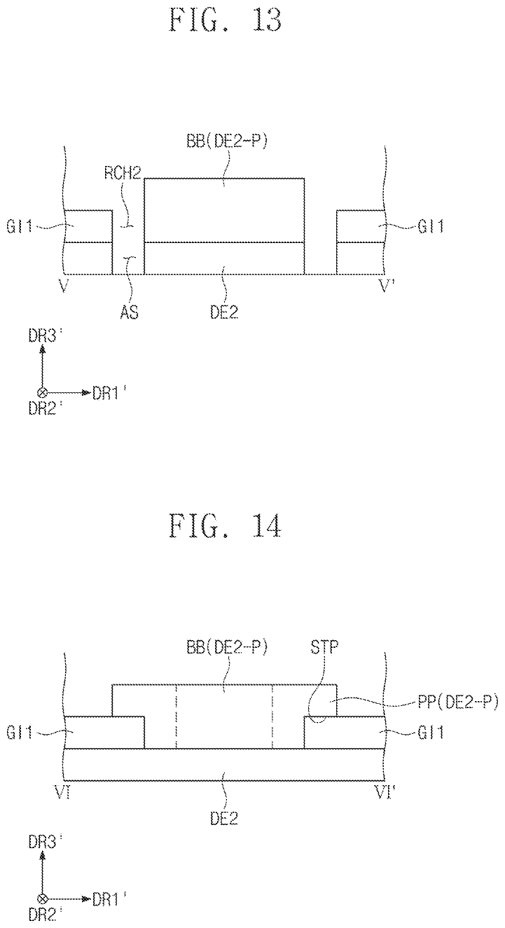

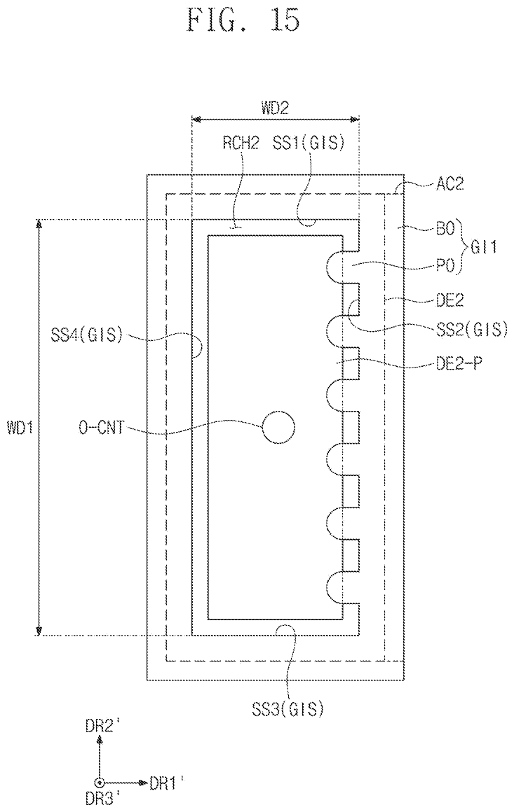

FIG. 14 is a cross-sectional view taken along the line VI-VI′ of FIG. 12 according to one or more embodiments of the present disclosure.

FIG. 14 illustrates a cross section of a region corresponding to a portion of the second protective pattern DE2-P in which the protective pattern protrusion portion PP is defined. According to FIG. 14, a portion of the protective pattern protrusion portion PP of the second protective pattern DE2-P may overlap the gate-insulating layer GI1. A step difference STP corresponding to the gate-insulating layer GI1 may be defined in the protective pattern protrusion portion PP.

FIG. 15 is a plan view of the portion AA of FIG. 8 according to one or more embodiments of the present disclosure. FIG. 15 illustrates one or more embodiments different from those in FIGS. 9 and 12.

Referring to FIG. 15, the widths of the second drain DE2, the second opening RCH2, and the second protective pattern DE2-P in the second direction DR2′ may be greater than the widths thereof in the first direction DR1′. As described above, because damage AS (see FIG. 10) does not occur in the portion of the second drain DE2 overlapping the insulating protrusion portion PO during a manufacturing process, current may flow smoothly through the second drain D2. A width WD1 of the second opening RCH2 in the second direction DR2′ may be greater than a width WD2 thereof in the first direction DR1′.

The inner side surface GIS of the gate-insulating layer GI1 defining the second opening RCH2 may include first to fourth surfaces SS1, SS2, SS3, and SS4. The second and fourth surfaces SS2 and SS4 in the second direction DR2′ may be longer than the first and third surfaces SS1 and SS3 in the first direction DR1′. The insulating protrusion portion PO may be provided in plurality, and the plurality of insulating protrusion portions PO may be located along the long surfaces SS2 and SS4. As illustrated in the drawing, the plurality of insulating protrusion portions PO may be located only on the second surface SS2, but without being limited thereto, they may be respectively located on the second surface SS2 and the fourth surface SS4, and are not particularly limited.

In this case, as portions of the second drain DE2 through which current flows are arranged in the long second direction DR2′, the sum of the widths of the portions of the second drain DE2 in the second direction DR2′, through which current flows, may increase. Because the magnitude of current flowing through the second drain DE2 is proportional to the width of a conductive region, the magnitude of current flowing through the second drain DE2 may increase.

The plurality of insulating protrusion portions PO may be located along the second surface SS2 closest to the second active region AC2 among the long surfaces SS2 and SS4. In this case, a distance between a portion of the second drain DE2, which overlaps the insulating protrusion portion PO and through which current flows, and the second active region AC2 may be shortened. Accordingly, a current path between the second drain DE2 and the second active region AC2 may be shortened and the magnitude of current flowing therethrough may increase.

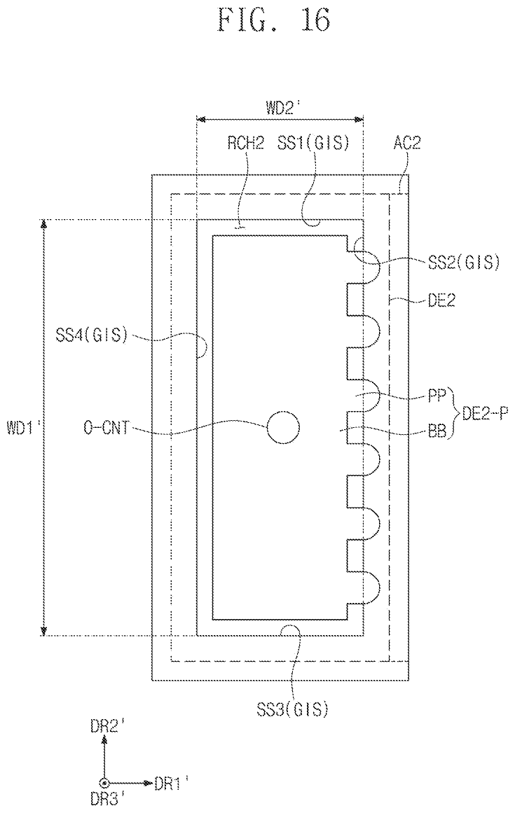

FIG. 16 is a plan view of the portion AA of FIG. 8 according to one or more embodiments of the present disclosure. FIG. 16 illustrates one or more embodiments different from that of FIG. 15. Hereinafter, descriptions of the same components as those described with reference to FIG. 15 will be omitted.

Referring to FIG. 16, the protective pattern protrusion portion PP may be provided in plurality. The plurality of protective pattern protrusion portions PP may protrude from the protective pattern body BB toward the gate-insulating layer GI1. As an example, the protective pattern protrusion portions PP may be located on portions of the protective pattern body BB that face the long surfaces SS2 and SS4. In this case, as described with reference to FIG. 15, because the width of a conductive portion increases, the magnitude of current flowing through the second drain DE2 may increase.

The plurality of protective pattern protrusion portions PP may be located on a portion of the surfaces of the gate-insulating layer GI1 that faces the second surface SS2 closest to the second active region AC2 among the long surfaces SS2 and SS4. As described with reference to FIG. 15, a current path between the second drain DE2 and the second active region AC2 may be shortened, and the magnitude of current flowing therethrough may increase.

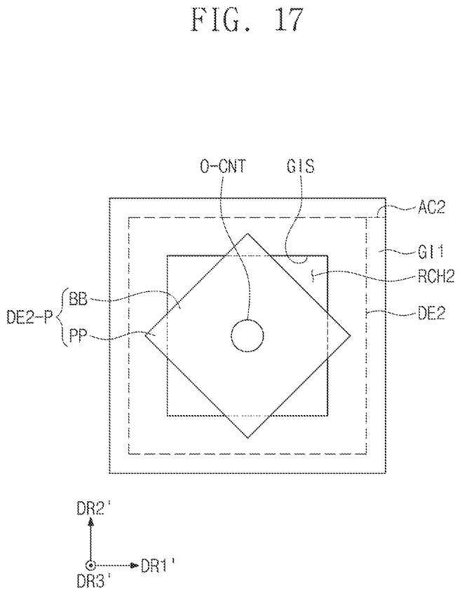

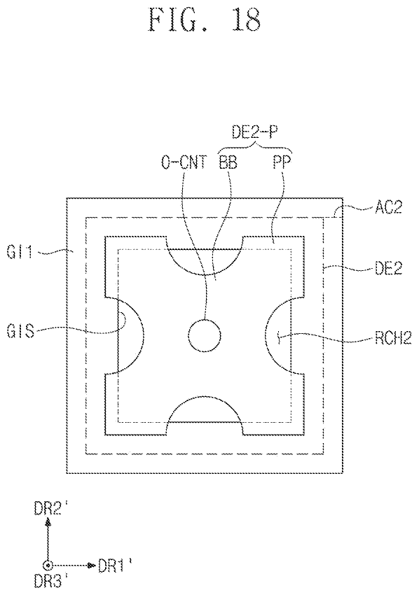

FIGS. 17 and 18 are plan views of the portion AA of FIG. 8 according to one or more embodiments of the present disclosure. FIGS. 17 and 18 illustrate embodiments different from the previous embodiments. Referring to FIGS. 17 and 18, the protective pattern protrusion portion PP may have various shapes.

Referring to FIG. 17, the protective pattern protrusion portion PP protruding from the protective pattern body BB may have a triangular shape in which the width thereof becomes narrower toward the outside. The second protective pattern DE2-P may have a square shape inclined or rotated at about 45 degrees. A portion adjacent to a corner of the second protective pattern DE2-P may overlap the gate-insulating layer GI1.

Referring to FIG. 18, the second protective pattern DE2-P may have a generally square shape that has a width that is larger than the width of the second opening RCH2, and that has a center of each edge recessed with a substantially uniform curvature. However, the shapes of the protective pattern protrusion portions PP illustrated in FIGS. 17 and 18 are only an example, and may be variously changed as suitable.

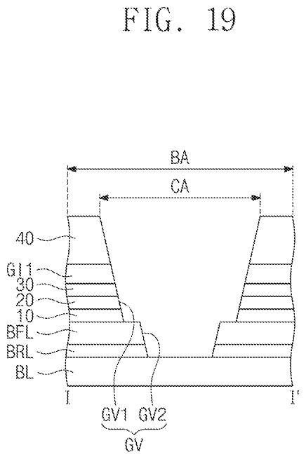

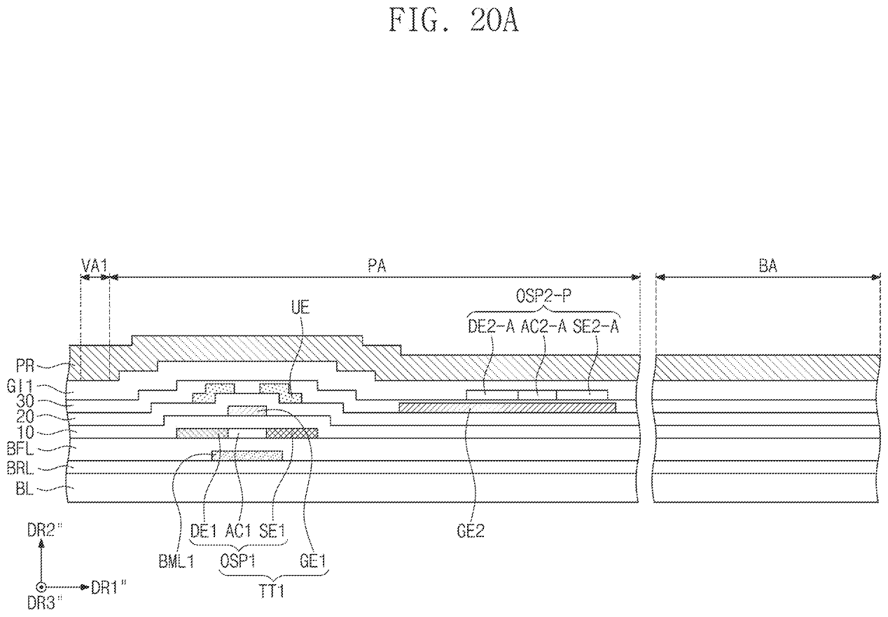

FIG. 19 is a cross-sectional view taken along the line I-l′ of FIG. 2 according to one or more embodiments of the present disclosure.

Referring to FIG. 19, a bending groove GV overlapping the bending region BA may be defined in the plurality of insulating layers 10, 20, 30, and 40 and the gate-insulating layer GI1. For example, the bending groove GV may correspond to a curvature region CA of the bending region BA. The curvature region CA may have a groove shape extending in one direction. The bending groove GV may include a first groove GV1 and a second groove GV2. The first groove GV1 may pass through the first to fourth insulating layers 10, 20, 30, and 40 and the gate-insulating layer GI1. The second groove GV2 may pass through the buffer layer BFL and the barrier layer BRL. However, the depths of the first groove GV1 and the second groove GV2 are not limited to the structure illustrated in FIG. 19, and may be changed. The bending groove GV may be formed concurrently or substantially simultaneously when the first to third contact holes G-CNT, P-CNT, and O-CNT are formed. This will be described later when a manufacturing method of the display device DD (see FIG. 4) is described with reference to FIGS. 20A to 20J.

FIGS. 20A to 20J are cross-sectional views illustrating some operations of a method of manufacturing a display device according to one or more embodiments of the present disclosure. Hereinafter, descriptions of the same components as those described above will be omitted.

Referring to FIG. 20A, there may be prepared a preliminary display device that includes a pixel region PA, a base layer including a boundary region VA (e.g., VA1), and a bending region BA, a first transistor TT1, a first back surface metal pattern BML1, a second gate GE2, a preliminary second semiconductor pattern OSP2-P, a third gate GE3, and a plurality of insulating layers 10, 20, 30, and GI1. The preliminary second semiconductor pattern OSP2-P may include a second gate region DE2-A, a second active region AC2-A, and a second source region SE2-A. A photoresist layer PR may be formed on the gate-insulating layer GI1.

FIG. 20A illustrates that the second gate GE2 is located on the second insulating layer 20, but the arrangement of the second gate GE2 is not limited thereto. For example, the second gate GE2 may be located on the same layer as the first gate GE1, and may include the same material as the first gate GE1. In this case, the second gate GE2 may be substituted with the first gate GE1.

For example, the second gate GE2 may be located on the same layer as the first back surface metal pattern BML1, and may include the same material as the first back surface metal pattern BML1. In this case, the second gate GE2 may be substituted with the first back surface metal pattern BML1.

Referring to FIG. 20B, the photoresist layer PR may be exposed to light by using a mask MK, which includes a light-transmissive region TA, a non-light-transmissive region NTA, and a semi-light-transmissive region HTA, and which is on the photoresist layer PR. The light-transmissive region TA may transmit light, and the non-light-transmissive region NTA may block light. The light transmittance of the semi-light-transmissive region HTA may be lower than that of the light-transmissive region TA. The light-transmissive region TA may correspond to the first contact hole G-CNT (see FIG. 8), the boundary opening V-HO (see FIG. 8), and the bending groove GV (see FIG. 19), and the semi-light-transmissive region HTA may correspond to the first opening RCH1 (see FIG. 8) and the second opening RCH2 (see FIG. 8).

When an exposure process and a development process are performed, a photoresist opening P-HO (e.g., see FIG. 20C) corresponding to the light-transmissive region TA may be formed, and a photoresist groove P-GU (e.g., see FIG. 20C) may be formed in the semi-light-transmissive region HTA. This utilizes a positive type-photoresist layer in which a light-receiving portion (a portion corresponding to the light-transmissive region TA) may be dissolved by a developing solution.

The photoresist layer PR corresponding to the light-transmissive region TA may receive light, and may be dissolved and removed by a developing solution. The photoresist layer PR corresponding to the non-light-transmissive region NTA may not receive light, and may not be dissolved and removed by a developing solution. Because the photoresist layer PR corresponding to the semi-light-transmissive region HTA may receive less light than the light-transmissive region TA, only a portion of the photoresist layer PR is dissolved and removed, and the remaining portion of the photoresist layer PR that has not been dissolved may remain.

However, the photoresist layer PR is not limited to the positive type, and it is possible to use a negative-type photoresist layer in which a portion (a portion corresponding to the non-transmissive region NTA) that does not receive light is dissolved by a developing solution. In this case, however, the positions of the light-transmissive region TA and the non-light-transmissive region NTA of the mask MK may be changed with each other.

Referring to FIG. 20C, a portion of the plurality of insulating layers 10, 20, 30, and GI1 may be etched through the photoresist opening P-HO. A preliminary boundary opening V-HOP may be formed by etching a portion of the plurality of insulating layers 10, 20, 30, and GI1 corresponding to the first boundary region VA1. A preliminary first groove GV1P may be formed by etching a portion of the plurality of insulating layers 10, 20, 30, and GI1 corresponding to the bending region BA A preliminary first contact hole G-CNTP may be formed by etching a portion of the plurality of insulating layers 10, 20, 30, and GI1 corresponding to the second gate GE2.

Referring to FIG. 20D, a portion of the photoresist layer PR may be developed. In this case, as the photoresist layer PR remaining in a portion corresponding to the semi-light-transmissive region HTA (see FIG. 20B) may be removed, a photoresist opening P-HO may be formed. Hereafter, a portion of the plurality of insulating layers 10, 20, 30, and GI1 may be etched through the photoresist opening P-HO. A boundary opening V-HO may be formed by etching a portion of the plurality of insulating layers 10, 20, 30, and GI1 corresponding to the first boundary region VA1. A first groove GV1 may be formed by etching a portion of the plurality of insulating layers 10, 20, 30, and GI1 corresponding to the bending region BA. A first contact hole G-CNT may be formed by etching a portion of the plurality of insulating layers 10, 20, 30, and GI1 corresponding to the second gate GE2. A first opening RCH1 and a second opening RCH2 may be formed by etching a portion of the plurality of insulating layers 10, 20, 30, and GI1 corresponding to the second drain region DE2-A and the second source region SE2-A.

Referring to FIGS. 20A to 20D, damage to the preliminary second semiconductor pattern OSP2-P may be reduced or minimized by using a half-tone mask including the semi-light-transmissive region HTA as the mask MK. In the etching operation of FIG. 20C, because a portion of the photoresist layer PR remains in a portion corresponding to the semi-light-transmissive region HTA and the photoresist groove P-GV is formed, the preliminary second semiconductor pattern OSP2-P may not be exposed to the outside. The first opening RCH1 and the second opening RCH2 may be formed only in the etching process of FIG. 20D. That is, as the first opening RCH1 and the second opening RCH2 are not formed in the etching operation of FIG. 20C, it is possible to reduce or prevent the likelihood of the preliminary second semiconductor pattern OSP2-P being etched and damaged through the first opening RCH1 and the second opening RCH2 later in the etching process of FIG. 20D.

In addition, through a series of processes of FIGS. 20A to 20D, the boundary opening V-HO, the first contact hole G-CNT, the first opening RCH1, the second opening RCH2, and the first groove GV1 may be formed concurrently or substantially simultaneously. Accordingly, it is possible to simplify the manufacturing process and reduce the manufacturing cost by reducing the number of necessary manufacturing processes.

Referring to FIG. 20E, a third gate GE3 may be formed, and may contact the second gate GE2 through the first contact hole G-CNT and the portion GI1-P of the gate-insulating layer. Although it is illustrated that the third gate GE3 on the left side of FIG. 20E and the third gate GE3 on the right side thereof are spaced apart from each other, they may be connected to each other on a plane as one gate.

In addition, a first protective pattern SE2-P located in the first opening RCH1, and a second protective pattern DE2-P located in the second opening RCH2, may be formed. The first protective pattern SE2-P and the second protective pattern DE2-P may include the same material as the third gate GE3, and may be formed through the same process as the third gate GE3.

Referring to FIG. 20F, a second semiconductor pattern OSP2 including a second drain DE2, a second active region AC2, and a second source SE2 may be formed by doping the preliminary second semiconductor pattern OSP2-P (see FIG. 20E). In the doping operation, the third gate GE3, the first protective pattern SE2-P, and the second protective pattern DE2-P may be used as a mask.

On a cross section, the outer side surfaces of the first and second protective patterns SE2-P and DE2-P may be spaced apart from the inner side surfaces of the gate-insulating layer GI1 (or the outer side surfaces of the portion GI1-P of the gate-insulating layer) defining the first opening RCH1 and the second opening RCH2 by a distance (e.g., predetermined distance) DT1. The second drain region DE2-A (see FIG. 20E) and the second source region SE2-A (see FIG. 20E) of the preliminary second semiconductor pattern OSP2-P (see FIG. 20E) may be doped by the distance DT1 by which the gate-insulating layer GI1 and the first and second protective patterns SE2-P and DE2-P are spaced apart from each other. Accordingly, it is possible to form a second transistor TT2 including the second semiconductor pattern OSP2, the second gate GE2, and the third gate GE3. In addition, an organic pattern OIP configured to fill the inside of the boundary opening V-HO may be formed.

Referring to FIG. 20G, a fourth insulating layer 40 configured to cover the second transistor TT2 and the organic pattern OIP may be formed. A photoresist layer PR may be formed on the fourth insulating layer 40.

Referring to FIG. 20H, the photoresist layer PR may be exposed to light by using a mask MK including a light-transmissive region TA and a non-light-transmissive region NTA. The position of the mask MK in FIG. 20H may be different from that of the mask MK in FIG. 20B in some regions. The light-transmissive region TA may correspond to the first source SE1, the first drain DE1, the second source SE2, the second drain DE2, and the bending region BA. Hereafter, a photoresist opening P-HO may be formed in the photoresist layer PR corresponding to the light-transmissive region TA through a developing process.

Referring to FIG. 20I, a portion of the plurality of insulating layers 10, 20, 30, 40, and GI1 may be etched through the photoresist opening P-HO. A second contact hole P-CNT may be formed by etching a portion of the plurality of insulating layers 10, 20, 30, 40, and GI1 corresponding to the first drain DE1 and the first source SE1. A third contact hole O-CNT may be formed by etching a portion of the plurality of insulating layers 10, 20, 30, 40, and GI1 corresponding to the second drain DE2 and the second source SE2. In this case, the second contact hole P-CNT may be formed on the first protective pattern SE2-P and the second protective pattern DE2-P. Accordingly, each of the first and second protective patterns SE2-P and DE2-P protects the second source SE2 and the second drain DE2 so that the second semiconductor pattern OSP2 may be protected from being damaged in the process of etching the third contact hole O-CNT.

A second groove GV2 may be formed by etching a portion of the plurality of insulating layers 10, 20, 30, 40, and GI1, the barrier layer BRL, and the buffer layer BFL corresponding to the bending region BA.

Referring to FIGS. 20H and 20I, the second contact hole P-CNT, the third contact hole O-CNT, and the second groove GV2 may be concurrently or substantially simultaneously formed. Accordingly, the manufacturing process may be simplified and the manufacturing cost may be reduced. However, as chemical treatment is required when the second contact hole P-CNT is etched, the semiconductor pattern OSP2, which is an oxide semiconductor vulnerable to chemical treatment, may be damaged when the second contact hole P-CNT and the third contact hole O-CNT are formed together. Accordingly, by forming the first protective pattern SE2-P and the second protective pattern DE2-P, as described above, damage to the second semiconductor pattern OSP2 may be reduced or minimized.

Referring to FIG. 20J, a first connection electrode CNE1 and a second connection electrode CNE2 may be formed on the fourth insulating layer 40. The first connection electrode CNE1 may come in contact with at least one of the first source SE1 or the first drain DE1 through the second contact hole P-CNT. The second connection electrode CNE2 may come in contact with any one of the first protective pattern SE2-P or the second protective pattern DE2-P through the third contact hole O-CNT.

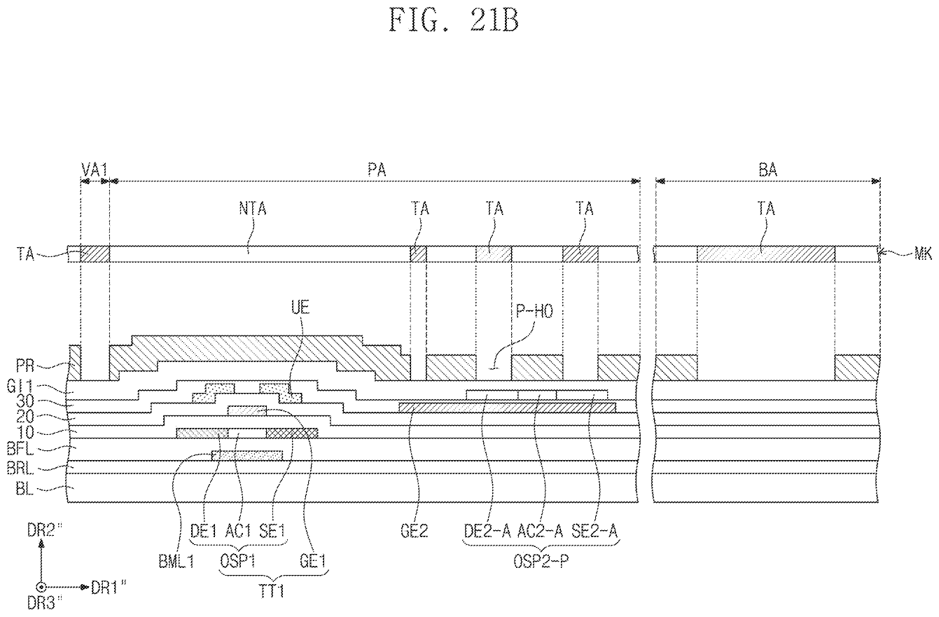

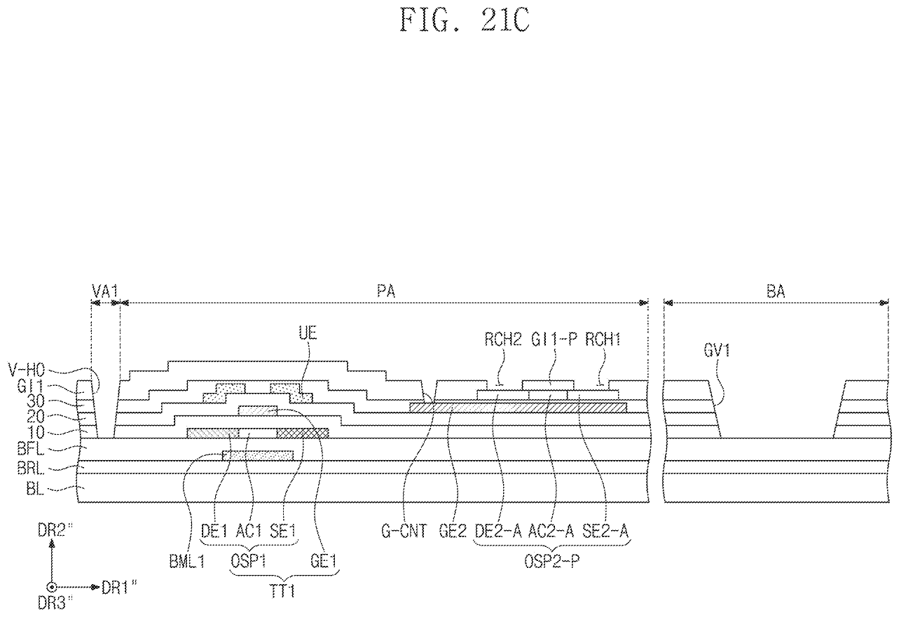

FIGS. 21A to 21C are cross-sectional views illustrating some operations of the method of manufacturing the display device according to one or more embodiments of the present disclosure. Hereinafter, descriptions of the same components as those described above will be omitted.

Referring to FIGS. 21A and 21B, the photoresist layer PR may be exposed to light by using a mask MK including a light-transmissive region TA and a non-light-transmissive region NTA on the photoresist layer PR. The light-transmissive region TA may correspond to the first contact hole G-CNT (see FIG. 8), the boundary opening V-HO (see FIG. 8), the first opening RCH1 (see FIG. 8), the second opening RCH2 (see FIG. 8), and the bending groove GV (see FIG. 8). Hereafter, through a developing process, a photoresist opening P-HO may be formed in a portion of the photoresist layer PR corresponding to the light-transmissive region TA.

Referring to FIG. 21C, at least a portion of the plurality of insulating layers 10, 20, 30, and GI1 may be etched through the photoresist opening P-HO. A boundary opening V-HO may be formed by etching the plurality of insulating layers 10, 20, 30, and GI1 corresponding to the first boundary region VA1. A first groove GV1 may be formed by etching the plurality of insulating layers 10, 20, 30, and GI1 corresponding to the bending region BA. A first contact hole G-CNT may be formed by etching a portion of the plurality of insulating layers 10, 20, 30, and GI1 corresponding to the second gate GE2. A first opening RCH1 and a second opening RCH2 may be formed by etching a portion of the plurality of insulating layers 10, 20, 30, and GI1 corresponding to the second source region SE2-A and the second drain region DE2-A.

Referring to FIGS. 21A to 21C, as the boundary opening V-HO, the first contact hole G-CNT, the first opening RCH1, the second opening RCH2, and the first groove GV1 may be formed in the same process as each other, it is possible to simplify the manufacturing process and reduce the manufacturing cost.

As described above, because the second semiconductor pattern is protected by the first protective pattern and the second protective pattern, it is possible to reduce or prevent damage to the second semiconductor pattern when a contact hole is formed.

In addition, because the second semiconductor pattern is protected by the first and second protective patterns, the second semiconductor pattern may not be damaged although a second contact hole, which connects the first semiconductor pattern and the connection electrode to each other, and a third contact hole, which connects the second semiconductor pattern and the connection electrode to each other, are concurrently or substantially simultaneously formed.

Accordingly, the manufacturing process may be simplified by forming the second and third contact holes in one process.

Although the above has been described with reference to preferred embodiments of the present disclosure, those skilled in the art or those of ordinary skill in the art will understand that various modifications and changes can be made to the present disclosure within the scope that does not depart from the spirit and technical field of the present disclosure described in the claims to be described later. Accordingly, the technical scope of the present disclosure should not be limited to the content described in the detailed description of the specification, but should be determined by the claims described hereinafter, with functional equivalents of the claims to be included therein.

What is claimed is:

1. A display device comprising:
a base layer;
a first transistor above the base layer, and comprising a first gate and a first semiconductor pattern comprising a first source, a first active region corresponding to the first gate, and a first drain;
a second transistor above the base layer and comprising an upper gate and a second semiconductor pattern comprising a second source, a second active region below the upper gate, and a second drain;
insulating layers covering the first transistor and the second transistor;
a gate-insulating layer covering the second active region, and in which a first opening corresponding to the second source, and a second opening corresponding to the second drain, are defined;
a first protective pattern in the first opening, above the second source, and comprising a same material as the upper gate; and
a second protective pattern in the second opening, above the second drain, and comprising a same material as the upper gate.

2. The display device of claim 1, wherein the second transistor further comprises a lower gate below the second active region,
wherein the lower gate and the upper gate are electrically connected to each other through a first contact hole passing through the gate-insulating layer and through a portion of the insulating layers between the lower gate and the upper gate, and
wherein at least any one of the lower gate or the upper gate is configured to receive a separate signal.

3. The display device of claim 2, wherein the lower gate is at a same layer as the first gate, and comprises a same material as the first gate.

4. The display device of claim 1, wherein a portion of the first protective pattern overlaps the gate-insulating layer,
wherein a remaining portion of the first protective pattern does not overlap the gate-insulating layer,
wherein a portion of the second protective pattern overlaps the gate-insulating layer, and
wherein a remaining portion of the second protective pattern does not overlap the gate-insulating layer.

5. The display device of claim 4, wherein an insulating protrusion portion is defined by an inner side surface of the gate-insulating layer, and
wherein at least a portion of the insulating protrusion portion overlaps the portion of the first protective pattern and the portion of the second protective pattern.

6. The display device of claim 5, wherein the insulating protrusion portion is provided in plurality, and
wherein the insulating protrusion portions are spaced apart from each other at regular intervals along the inner side surface.

7. The display device of claim 5, wherein the inner side surface comprises a first surface, and a second surface that is longer than the first surface,
wherein the insulating protrusion portion is provided in plurality,
wherein the insulating protrusion portions are arranged along the second surface, and
wherein the second surface is closer to the second active region than the first surface.

8. The display device of claim 4, wherein the first protective pattern and the second protective pattern comprise a protective pattern body, and a protective pattern protrusion portion protruding from the protective pattern body, and
wherein at least a portion of the protective pattern protrusion portion overlaps the gate-insulating layer.

9. The display device of claim 8, wherein the protective pattern protrusion portion is provided in plurality, and
wherein the protective pattern protrusion portions are spaced apart from each other along an outer side surface of each of the first protective pattern and the second protective pattern.

10. The display device of claim 8, wherein an inner side surface of the gate-insulating layer defining the opening comprises a first surface, and a second surface that is longer than the first surface,
wherein the protective pattern protrusion portion is provided in plurality,
wherein the protective pattern protrusion portions are arranged along the second surface, and
wherein the second surface among the inner side surfaces is closest to the second active region.

11. The display device of claim 1, wherein a portion of the gate-insulating layer contacts a lower surface of the upper gate and contacts an upper surface of the second active region.

12. The display device of claim 1, further comprising:
a first connection electrode contacting at least one of the first source or the first drain through a second contact hole passing through the insulating layers and the gate-insulating layer; and
a second connection electrode contacting at least one of the first protective pattern or the second protective pattern through a third contact hole passing through the insulating layers and the gate-insulating layer.

13. The display device of claim 1, wherein the first semiconductor pattern comprises a polysilicon semiconductor, and
wherein the second semiconductor pattern comprises an oxide semiconductor.

14. The display device of claim 1, wherein the base layer comprises a pixel region overlapping the first transistor and the second transistor, and a boundary region adjacent to the pixel region, and
wherein a boundary opening corresponding to the boundary region is defined by the insulating layers and the gate-insulating layer.

15. The display device of claim 1, wherein the base layer comprises a non-bending region, and a bending region that is bendable and that is adjacent to the non-bending region, and
wherein a bending groove overlapping the bending region is defined by the insulating layers and the gate-insulating layer.

16. A method for manufacturing a display device, the method comprising:
preparing a preliminary display device comprising:
a base layer comprising:
a display region comprising a pixel region, and a boundary region adjacent to the pixel region; and
a non-display region comprising a bending region that is bendable;
a first transistor comprising a first gate, and a first semiconductor pattern comprising a first source, a first active region, and a first drain;
a preliminary second transistor comprising a lower gate and a preliminary second semiconductor pattern; and
a lower insulating layer covering the first transistor and the preliminary second transistor;
forming a first contact hole overlapping the lower gate in the lower insulating layer;
forming a first opening overlapping a second source region of the preliminary second transistor in the lower insulating layer;
forming a second opening overlapping a second drain region of the preliminary second transistor in the lower insulating layer;
forming an upper gate contacting the lower gate through the first contact hole;
forming a first protective pattern in the first opening;
forming a second protective pattern in the second opening;
forming a second transistor by forming a second semiconductor pattern comprising a second source, a second active region, and a second drain from the preliminary second semiconductor pattern;
forming an upper insulating layer covering the second transistor; and
substantially simultaneously forming a second contact hole defined by the upper insulating layer and the lower insulating layer, and corresponding to each of the first source and the first drain, and a third contact hole defined by the upper insulating layer and the lower insulating layer, and corresponding to each of the second source and the second drain.

17. The method of claim 16, wherein, in the forming of the first contact hole, the forming the first opening, and the forming the second opening, a boundary opening corresponding to the boundary region is substantially simultaneously formed in the lower insulating layer.

18. The method of claim 16, wherein, in the forming of the first contact hole, forming the first opening, and forming the second opening, a bending groove overlapping the bending region is substantially simultaneously formed in the lower insulating layer.

19. The method of claim 16, wherein the forming of the first contact hole, the forming of the first opening, and the forming of the second opening comprises:
forming a photoresist layer on the lower insulating layer; and
exposing the photoresist layer to light using a mask comprising a light-transmissive region, a non-light-transmissive region, and a semi-light-transmissive region on the photoresist layer,
wherein the semi-light-transmissive region corresponds to the first opening and the second opening, and
wherein the light-transmissive region corresponds to the first contact hole.

20. The method of claim 16, wherein the forming of the first contact hole, the forming of the first opening, and the forming of the second opening comprises:
forming a photoresist layer on the lower insulating layer; and
exposing the photoresist layer to light using a mask comprising a light-transmissive region and a non-light-transmissive region on the photoresist layer,
wherein the light-transmissive region corresponds to the first contact hole, the first opening, and the second opening.
